(19) United States
(12) Patent Application Publication
(10) Pub. No.: US 2026/0301844 A1
(43) Pub. Date: Oct. 1, 2026

(54) NON-VOLATILE MEMORY WITH INTEGRATED ARTIFICIAL INTELLIGENCE AND UPDATING MODEL

(71) Applicant: Sandisk Technologies, Inc., Milpitas, CA (US)

(72) Inventors: Sixiang ZHAO, Shanghai (CN); Xuan TIAN, Shanghai (CN); Liang LI, Shanghai (CN); Ming WANG, Shanghai (CN)

(73) Assignee: Sandisk Technologies, Inc., Milpitas, CA (US)

(21) Appl. No.: 19/093,966

(22) Filed: Mar. 28, 2025

(51) Int. Cl. G11C 29/52; G06N 3/063; G11C 29/02

(52) U.S. Cl. CPC G11C 29/52; G06N 3/063; G11C 29/022

(57) ABSTRACT

A non-volatile memory system stores a pre-trained model in non-volatile memory cells. The model was received pre-trained from a source external to the non-volatile memory system. The non-volatile memory system further includes an inference engine circuit that uses the model with one or more metrics gathered during operation of the non-volatile memory system to attempt to predict defects in the non-volatile memory. In some cases, however, a block (or other grouping) of memory cells fails (e.g., a memory operation fails) despite that the inference engine predicted that the block of memory cells would not fail. In response to the prediction being wrong, the non-volatile memory system gathers one or more metrics describing the operation of the non-volatile memory system when the block failed (or metrics describing the operation of the non-volatile memory system when multiple blocks failed) and uses those metrics to update the model.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery). One example of non-volatile memory is flash memory (e.g., NAND-type and NOR-type flash memory).

Users of non-volatile memory can program (e.g., write) data to the non-volatile memory and later read that data back. For example, a digital camera may take a photograph and store the photograph in non-volatile memory. Later, a user of the digital camera may view the photograph by having the digital camera read the photograph from the non-volatile memory. Because users often rely on the data they store, it is important to users of non-volatile memory to be able to store data reliably so that it can be read back successfully.

### BRIEF DESCRIPTION OF THE DRAWINGS

Like-numbered elements refer to common components in the different figures.

FIG. 1 is a block diagram depicting one embodiment of a storage system.

FIG. 2 is a block diagram depicting one embodiment of a plurality of memory die assemblies.

FIG. 2A is a block diagram of one embodiment of a memory die.

FIG. 2B is a block diagram of one embodiment of an integrated memory assembly.

FIGS. 2C and 2D depict different embodiments of integrated memory assemblies.

FIG. 3 depicts circuitry used to sense data from non-volatile memory.

FIG. 4 is a perspective view of a portion of one embodiment of a monolithic three dimensional memory structure.

FIG. 4A is a block diagram of one embodiment of a memory structure having two planes.

FIG. 4B depicts a top view of a portion of one embodiment of a block of memory cells.

FIG. 4C depicts a cross sectional view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G depicts a cross section of as memory hole that implements a vertical NAND string.

FIG. 4H depicts a cross section of as memory hole that implements a vertical NAND string.

FIG. 4I depicts a cross section of as memory hole that implements a vertical NAND string.

FIG. 4J is a schematic of a plurality of NAND strings in multiple sub-blocks of a same block.

FIG. 5A depicts threshold voltage distributions.

FIG. 5B depicts threshold voltage distributions.

FIG. 5C depicts threshold voltage distributions.

FIG. 5D depicts threshold voltage distributions.

FIG. 6 is a flow chart describing one embodiment of a process for programming non-volatile memory.

FIG. 7 is a flow chart describing one embodiment of a process for operating non-volatile memory and performing defect management using Artificial Intelligence with an updating model.

FIG. 8 is a flow chart describing one embodiment of a process for training a model.

FIG. 9 is a flow chart describing one embodiment of a process for inferencing in order to predict defects in non-volatile memory.

FIG. 10 is a flow chart describing one embodiment of a process for inferencing and updating a pre-trained model.

FIG. 11 is a flow chart describing one embodiment of a process for updating a pre-trained model.

### DETAILED DESCRIPTION

In order to more reliably store data in non-volatile memory storage system, a memory health management system based on machine learning is used to predict a defect in the storage system before there is a failure that can affect the data being stored.

A non-volatile memory system stores a pre-trained model in non-volatile memory cells. The model was received pre-trained from a source external to the non-volatile memory system. The non-volatile memory system further includes an inference engine circuit that uses the pre-trained model with one or more metrics gathered during operation of the non-volatile memory system to attempt to predict defects in the non-volatile memory and perform countermeasures to preserve host data prior to a non-recoverable failure in the non-volatile memory due to the defect.

However, to maintain good performance, the pre-trained model needs to be updated and/or optimized. For example, in some cases a block (or other grouping) of memory cells fails (e.g., a memory operation fails) despite that the inference engine circuit predicted that the block of memory cells would not fail. In response to the prediction being wrong, the non-volatile memory system gathers one or more metrics describing the operation of the non-volatile memory system when the block failed (or metrics describing the operation of the non-volatile memory system when multiple blocks failed) and uses those metrics to update and/or optimize the pre-trained model that is stored within the non-volatile memory system.

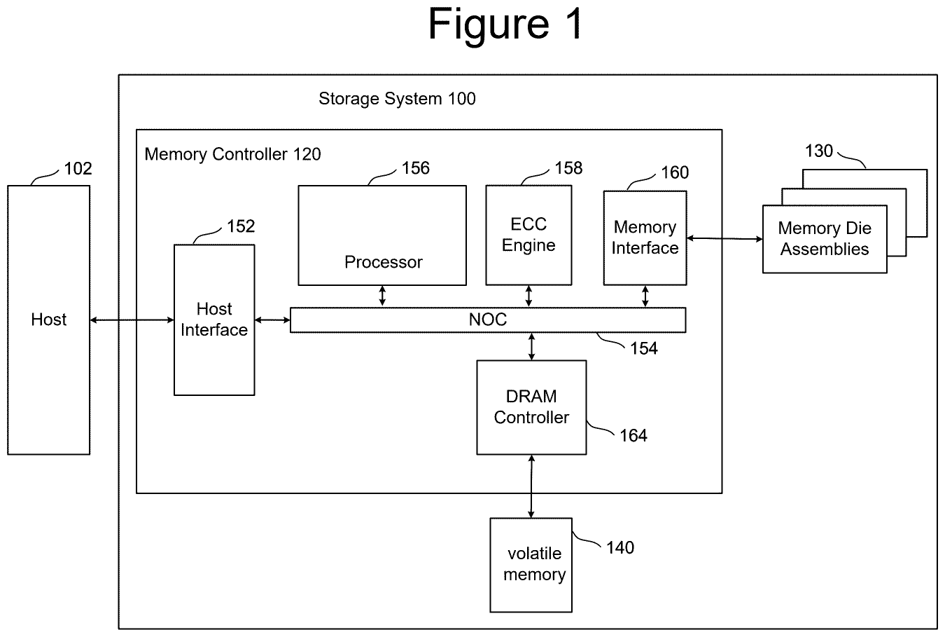

FIG. 1 is a block diagram of one embodiment of a storage system 100 that implements the proposed technology described herein. In one embodiment, storage system 100 is a solid state drive (“SSD”). Storage system 100 can also be a memory card, USB drive or other type of storage system. The proposed technology is not limited to any one type of memory system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 connected to one or more memory die assemblies 130 and local high speed volatile memory 140 (e.g., DRAM). Local high speed volatile memory 140 is used by memory controller 120 to perform certain functions. For example, local high speed volatile memory 140 stores logical to physical address translation tables (“L2P tables”).

Memory controller 120 comprises a host interface 152 that is connected to and in communication with host 102. In one embodiment, host interface 152 implements a NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction services. For example, ECC engine 158 performs data encoding and decoding, as per the implemented ECC technique. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory dies. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in the one or more memory die assemblies 130 and a subset of the L2P tables are cached (L2P cache) in the local high speed volatile memory 140.

Memory interface 160 communicates with the one or more memory die assemblies 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

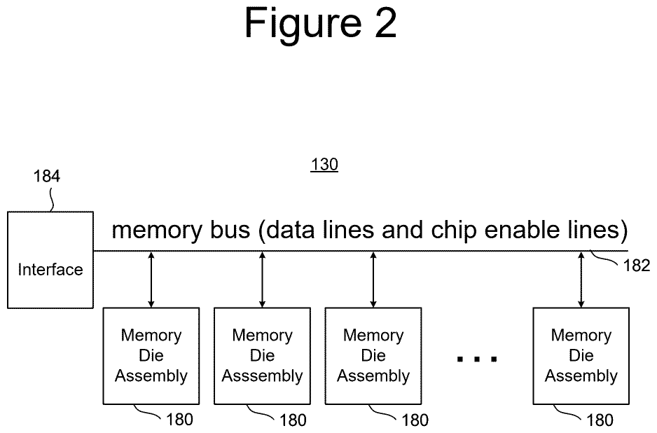

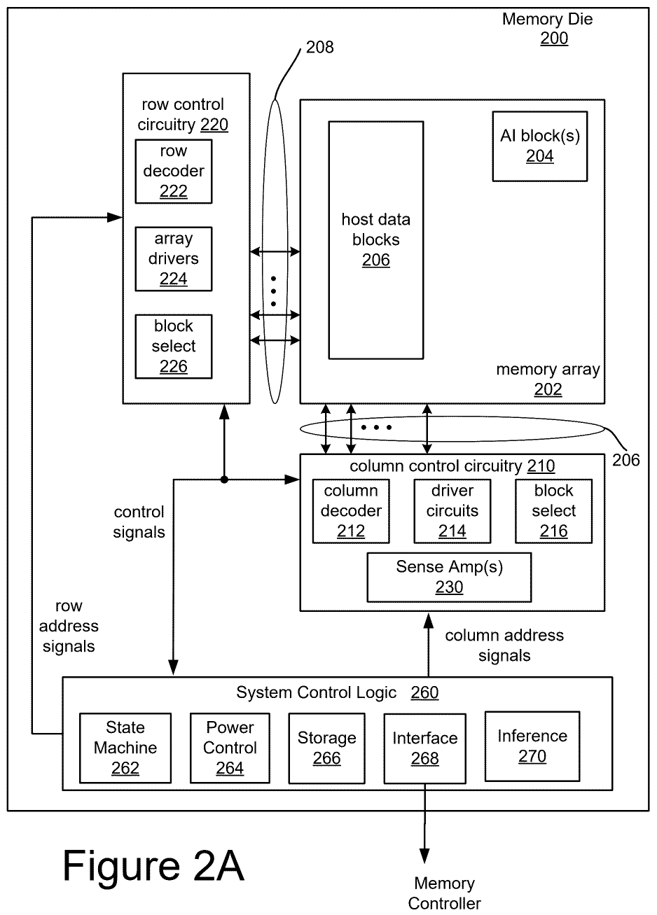

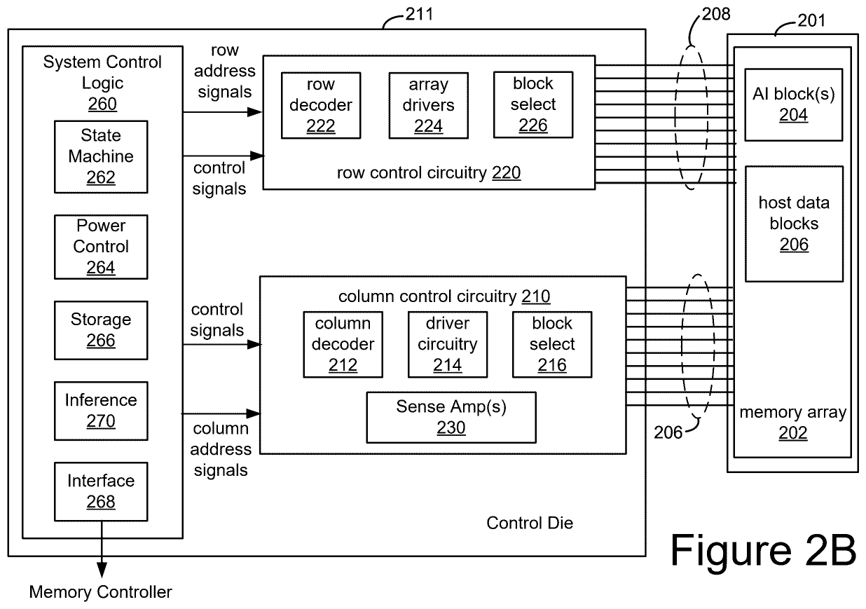

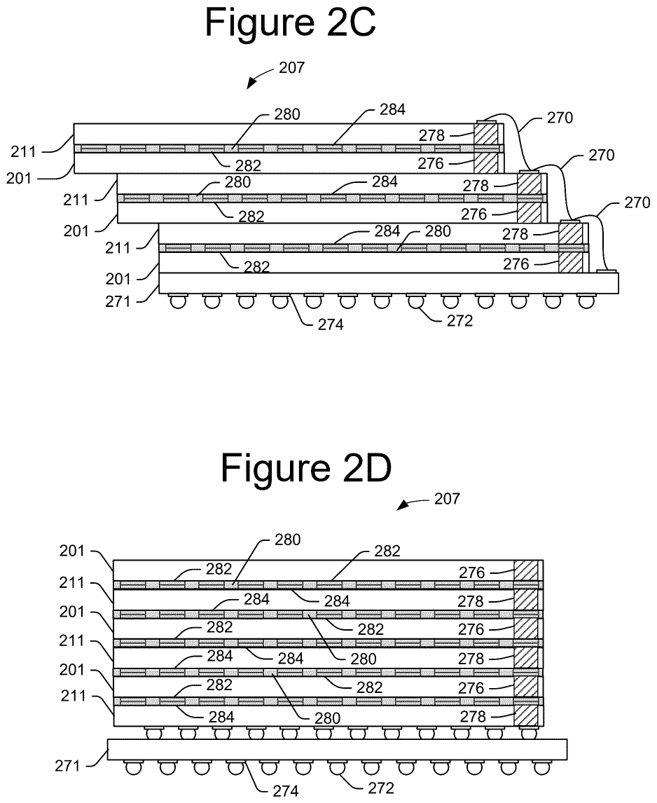

FIG. 2 is a block diagram depicting one embodiment of the one or more memory die assemblies 130 of FIG. 1. FIG. 2 shows the one or more memory die assemblies 130 comprises a plurality of individual memory die assemblies 180 connected to a memory bus (data lines and chip enable lines) 182. The memory bus 182 connects to interface 184 (e.g., a Toggle Mode Interface) for communicating with memory controller 120. The technology described herein is not limited to any particular number of memory die assemblies 180.

FIG. 2A is a functional block diagram of memory die 200, which is one embodiment of a memory die assembly 180. The components depicted in FIG. 2A are electrical circuits. Memory die 200 includes a non-volatile memory array 202 (which is one example of a non-volatile memory structure) that can comprises non-volatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic circuit 206, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 262 can also include a power control module 264 that controls the power and voltages supplied to the rows and columns of the memory array 202 during memory operations and may include charge pumps and regulator circuit for creating regulating voltages. System control logic 262 includes storage 366 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 360, can be formed as part of a single die. In other embodiments, some or all of the system control logic 260 can be formed on a different die.

In one embodiment, memory array 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory array 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory array 202 is not limited to the examples above. Many different types of memory array architectures or memory technologies can be used to form memory array 202. No particular non-volatile memory technology is required for purposes of the new claimed embodiments proposed herein. Other examples of suitable technologies for memory cells of the memory array/structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory array 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

In one embodiment, memory array 202 comprises a first set of non-volatile memory cells 206 configured to store host data and a second set of non-volatile memory cells 204 that store one or more pre-trained models received pre-trained from a source external to the non-volatile storage apparatus. In one embodiment, the second set of non-volatile memory cells 204 that store the pre-trained models comprises one or more blocks of memory cells (e.g., one or more erase blocks dedicated to storing the pre-trained model, where an erase block is the unit of erase), referred to as Artificial Intelligence (“AI”) block(s). More details about the pre-trained model are provided below.

In one embodiment, the System Control Logic 260 (e.g., which is configured to write to and read from the memory array 202) further includes an inference engine circuit 270 (e.g., an electrical circuit), which is also referred to as an AI circuit. In the embodiment of FIG. 2A, the inference engine circuit 270 and the memory array are positioned in the memory die assembly (e.g. on memory die 200). In one embodiment, inference engine circuit 270, is configured to use the pre-trained model from the second set of non-volatile memory cells 204 (AI blocks) with one or more metrics describing current operation of storage system 100 in order to predict a defect in the storage system 100 and perform a countermeasure to preserve the host data prior to a non-recoverable failure in the storage system 100 due to the defect. More details are provided below.

The elements of FIG. 2A can be grouped into two parts: (1) memory array 202 and (2) peripheral circuitry, where peripheral circuitry includes all of the components depicted in FIG. 2A other than memory array 202. An important characteristic of a memory circuit is its capacity, which can be increased by increasing the area of the memory die of storage system 100 that is given over to the memory array 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory array 202 and the amount of area to devote to the peripheral circuitry.

Another area in which the memory array 202 and the peripheral circuitry are often at odds is in the processing involved in forming these regions, since these regions often involve differing processing technologies and the trade-off in having differing technologies on a single die. For example, when the memory array 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory array 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair comprising a memory die and a control die. In that regard, FIG. 2B is a functional block diagram of integrated memory assembly 207, which is another embodiment of a memory die assembly 180. The components depicted in FIG. 2B are electrical circuits. The integrated memory assembly 207 includes two types of semiconductor die (or more succinctly, “die”). Memory die 201 includes memory array 202. Memory array 202 includes non-volatile memory cells. Control die 211 includes control circuitry 260, 210, and 220 (as described above). In some embodiments, control die 211 is configured to connect to the memory array 202 in the memory die 201. In some embodiments, the memory die 201 and the control die 211 are bonded together.

FIG. 2B shows an example of the peripheral circuitry, including control circuits, formed in a peripheral circuit or control die 211 coupled to memory array 202 formed in memory die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory die 201. In some embodiments, some of the circuitry in the system control logic 260 is located on the on the memory die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory array 202 on the memory die 201 through electrical paths 206. For example, electrical paths 206 may provide electrical connection between column decoder 212, driver circuitry 214, and block select 216 and bit lines of memory array 202. Electrical paths may extend from column control circuitry 210 in control die 211 through pads on control die 211 that are bonded to corresponding pads of the memory die 201, which are connected to bit lines of memory array 202. Each bit line of memory array 202 may have a corresponding electrical path in electrical paths 306, including a pair of bond pads, which connects to column control circuitry 210. Similarly, row control circuitry 220, including row decoder 222, array drivers 224, and block select 226 are coupled to memory array 202 through electrical paths 208. Each of electrical path 208 may correspond to a word line, dummy word line, or select gate line. Additional electrical paths may also be provided between control die 211 and memory die 201.

As in FIG. 2A, the system control logic 260 of FIG. 2B includes inference engine circuit 270 which is configured to use the pre-trained model from the second set of non-volatile memory cells 204 with one or more metrics describing current operation of storage system 100 in order to predict a defect in the storage system 100 and perform a countermeasure to preserve the host data prior to a non-recoverable failure in the storage system 100 due to the defect. Thus, FIG. 2B depicts an embodiment in which the memory die assembly comprises a memory die bonded to control die, the non-volatile memory is positioned on the memory die, and the inference circuit is positioned on the control die.

For purposes of this document, the phrases “a control circuit” or “one or more control circuits” can include any one of or any combination of memory controller 120, state machine 262, all or a portion of system control logic 260 (e.g., including inference engine circuit 270), all or a portion of row control circuitry 220, all or a portion of column control circuitry 210, a microcontroller, a microprocessor, and/or other similar functioned circuits. The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit. In another example, the control circuit can include memory controller 120 in combination with all of the components of FIG. 2A or 2B, excluding memory array 202.

In some embodiments, there is more than one control die 211 and more than one memory die 201 in an integrated memory assembly 207. In some embodiments, the integrated memory assembly 207 includes a stack of multiple control die 211 and multiple memory die 201. FIG. 2C depicts a side view of an embodiment of an integrated memory assembly 207 stacked on a substrate 271 (e.g., a stack comprising control dies 211 and memory dies 201). The integrated memory assembly 207 has three control dies 211 and three memory dies 201. In some embodiments, there are more than three memory dies 201 and more than three control die 211.

Each control die 211 is affixed (e.g., bonded) to at least one of the memory dies 201. Some of the bond pads 282/284 are depicted. There may be many more bond pads. A space between two dies 201, 211 that are bonded together is filled with a solid layer 280, which may be formed from epoxy or other resin or polymer. This solid layer 280 protects the electrical connections between the dies 201, 211, and further secures the dies together. Various materials may be used as solid layer 280, but in embodiments, it may be Hysol epoxy resin from Henkel Corp., having offices in California, USA.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 2C).

A memory die through silicon via (TSV) 276 may be used to route signals through a memory die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 2D depicts a side view of another embodiment of an integrated memory assembly 207 stacked on a substrate 271. The integrated memory assembly 206 of FIG. 2D has three control die 211 and three memory die 201. In some embodiments, there are many more than three memory dies 201 and many more than three control dies 211. In this example, each control die 211 is bonded to at least one memory die 201. Optionally, a control die 211 may be bonded to two or more memory die 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 2C, the integrated memory assembly 207 in FIG. 2D does not have a stepped offset. A memory die through silicon via (TSV) 276 may be used to route signals through a memory die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory die 201 may be bonded together. Bond pads on each die 201, 211 may be used to bond the two dies together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor dies including the bond pads. The film layer is provided around the bond pads. When the dies are brought together, the bond pads may bond to each other, and the film layers on the respective dies may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the dies may be under filled with an epoxy or other resin or polymer. The under-fill material may be applied as a liquid which then hardens into a solid layer. This under-fill step protects the electrical connections between the dies 201, 211, and further secures the dies together. Various materials may be used as under-fill material, but in embodiments, it may be Hysol epoxy resin from Henkel Corp., having offices in California, USA.

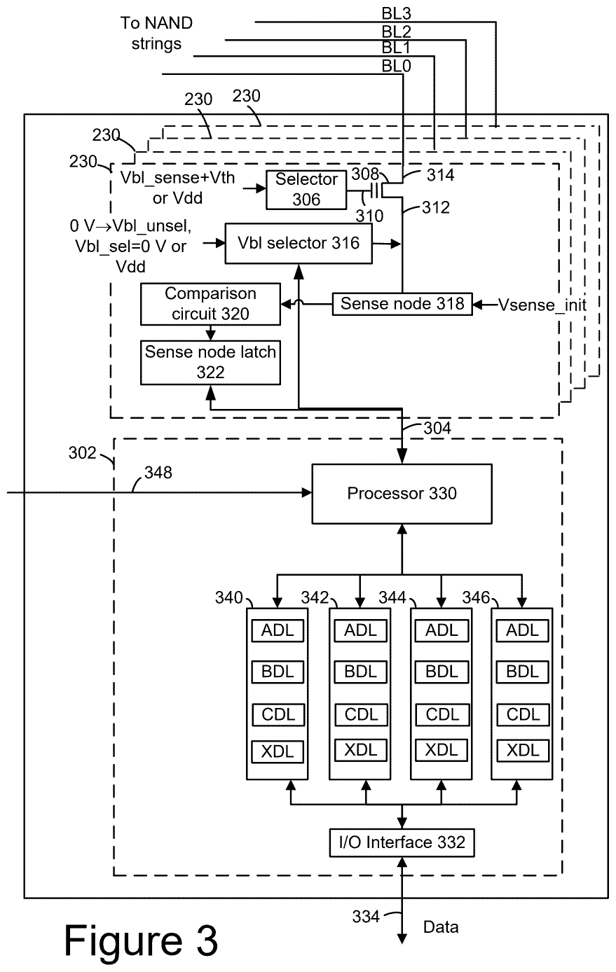

FIG. 3 is a block diagram depicting one embodiment of a portion of column control circuitry 210 that is partitioned into a plurality of sense amplifiers 230, and a common portion, referred to as a managing circuit 302. In one embodiment, each sense amplifier 230 is connected to a respective bit line which in turn is connected to one or more NAND strings. In one example implementation, each bit line is connected to six NAND strings, with one NAND string per sub-block. Managing circuit 302 is connected to a set of multiple (e.g., four, eight, etc.) sense amplifiers 230. Each of the sense amplifiers 230 in a group communicates with the associated managing circuit via data bus 304.

Each sense amplifier 230 operates to provide voltages to bit lines (see BL0, BL1, BL2, BL3) during program, verify, erase and read operations. Sense amplifiers are also used to sense the condition (e.g., data state) to a memory cells in a NAND string connected to the bit line that connects to the respective sense amplifier.

Each sense amplifier 230 includes a selector 306 or switch connected to a transistor 308 (e.g., an nMOS). Based on voltages at the control gate 310 and drain 312 of the transistor 308, the transistor can operate as a pass gate or as a bit line clamp. When the voltage at the control gate is sufficiently higher than the voltage on the drain, the transistor operates as a pass gate to pass the voltage at the drain to the bit line (BL) at the source 314 of the transistor. For example, a program-inhibit voltage such as 1-2 V may be passed when pre-charging and inhibiting an unselected NAND string. Or, a program-enable voltage such as 0 V may be passed to allow programming in a selected NAND string. The selector 306 may pass a power supply voltage Vdd, (e.g., 3-4 V) to the control gate of the transistor 308 to cause it to operate as a pass gate.

When the voltage at the control gate is lower than the voltage on the drain, the transistor 308 operates as a source-follower to set or clamp the bit line voltage at Vcg−Vth, where Vcg is the voltage on the control gate 310 and Vth, e.g., 0.7 V, is the threshold voltage of the transistor 308. This assumes the source line is at 0 V. If Vcelsrc is non-zero, the bit line voltage is clamped at Vcg−Vcelsrc−Vth. The transistor is therefore sometimes referred to as a bit line clamp (BLC) transistor, and the voltage Veg on the control gate 310 is referred to as a bit line clamp voltage, Vblc. This mode can be used during sensing operations such as read and verify operations. The bit line voltage is thus set by the transistor 308 based on the voltage output by the selector 306. For example, the selector 306 may pass Vsense+Vth, e.g., 1.5 V, to the control gate of the transistor 308 to provide Vsense, e.g., 0.8 V, on the bit line. A Vbl selector 316 may pass a relatively high voltage such as Vdd to the drain 312, which is higher than the control gate voltage on the transistor 308, to provide the source-follower mode during sensing operations. Vbl refers to the bit line voltage.

The Vbl selector 316 can pass one of a number of voltage signals. For example, the Vbl selector can pass a program-inhibit voltage signal which increases from an initial voltage, e.g., 0 V, to a program inhibit voltage, e.g., Vbl_inh for respective bit lines of unselected NAND string during a program loop. The Vbl selector 316 can pass a program-enable voltage signal such as 0 V for respective bit lines of selected NAND strings during a program loop.

In one approach, the selector 306 of each sense circuit can be controlled separately from the selectors of other sense circuits. The Vbl selector 316 of each sense circuit can also be controlled separately from the Vbl selectors of other sense circuits.

During sensing, a sense node 318 is charged up to an initial voltage, Vsense_init, such as 3 V. The sense node is then passed to the bit line via the transistor 308, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell <=Iref, the memory cell is in a non-conductive state and if Icell>Iref, the memory cell is in a conductive state.

In particular, the comparison circuit 320 determines the amount of decay by comparing the sense node voltage to a trip voltage at a sense time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the verify voltage. A sense node latch 322 is set to 0 or 1, for example, by the comparison circuit 320 based on whether the memory cell is in a conductive or non-conductive state, respectively. For example, in a program-verify test, a 0 can denote fail and a 1 can denote pass. The bit in the sense node latch can be read out in a state bit scan operation of a scan operation or flipped from 0 to 1 in a fill operation. The bit in the sense node latch 322 can also be used in a lockout scan to decide whether to set a bit line voltage to an inhibit or program level in a next program loop. L

Managing circuit 302 comprises a processor 330, four example sets of data latches 340, 342, 344 and 346, and an I/O interface 332 coupled between the sets of data latches and the data bus 334. FIG. 3 shows four example sets of data latches 340, 342, 344 and 346; however, in other embodiments more or less than four can be implemented. In one embodiment, there is one set of latches for each sense amplifier 230. One set of three data latches, e.g., comprising individual latches ADL, BDL, CDL and XDL, can be provided for each sense circuit. In some cases, a different number of data latches may be used. In a three bit per memory cell embodiment, ADL stores a bit for a lower page of data, BDL stores a bit for a middle page of data, CDL stores a bit for an upper page of data and XDL serves as an interface latch for storing/latching data from the memory controller.

Processor 330 performs computations, such as to determine the data stored in the sensed memory cell and store the determined data in the set of data latches. Each set of data latches 340-346 is used to store data bits determined by processor 330 during a read operation, and to store data bits imported from the data bus 334 during a program operation which represent write data meant to be programmed into the memory. I/O interface 332 provides an interface between data latches 340-346 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to processor 330 via the data bus 304. At that point, processor 330 determines the resultant memory state by consideration of the tripping event(s) of the sense circuit and the information about the applied control gate voltage from the state machine via input lines 348. It then computes a binary encoding for the memory state and stores the resultant data bits into data latches 340-346.

Some implementations can include multiple processors 330. In one embodiment, each processor 330 will include an output line (not depicted) such that each of the output lines is connected in a wired-OR connection. A wired OR connection or line can be provided by connecting multiple wires together at a node, where each wire carries a high or low input signal from a respective processor, and an output of the node is high if any of the input signals is high. In some embodiments, the output lines are inverted prior to being connected to the wired-OR line. This configuration enables a quick determination during a program verify test of when the programming process has completed because the state machine receiving the wired-OR can determine when all bits being programmed have reached the desired level. For example, when each bit has reached its desired level, a logic zero for that bit will be sent to the wired-OR line (or a data one is inverted). When all bits output a data 0 (or a data one inverted), then the state machine knows to terminate the programming process. Because each processor communicates with eight sense circuits, the state machine needs to read the wired-OR line eight times, or logic is added to processor 330 to accumulate the results of the associated bit lines such that the state machine need only read the wired-OR line one time. Similarly, by choosing the logic levels correctly, the global state machine can detect when the first bit changes its state and change the algorithms accordingly.

During program or verify operations for memory cells, the data to be programmed (write data) is stored in the set of data latches 340-346 from the data bus 334. During reprogramming, a respective set of data latches of a memory cell can store data indicating when to enable the memory cell for reprogramming based on the program pulse magnitude.

The program operation, under the control of the state machine 262, applies a series of programming voltage pulses to the control gates of the addressed memory cells. Each voltage pulse may be stepped up in magnitude from a previous program pulse by a step size in a processed referred to as incremental step pulse programming. Each program voltage is followed by a verify operation to determine if the memory cells has been programmed to the desired memory state. In some cases, processor 330 monitors the read back memory state relative to the desired memory state. When the two are in agreement, processor 330 sets the bit line in a program inhibit mode such as by updating its latches. This inhibits the memory cell coupled to the bit line from further programming even if additional program pulses are applied to its control gate.

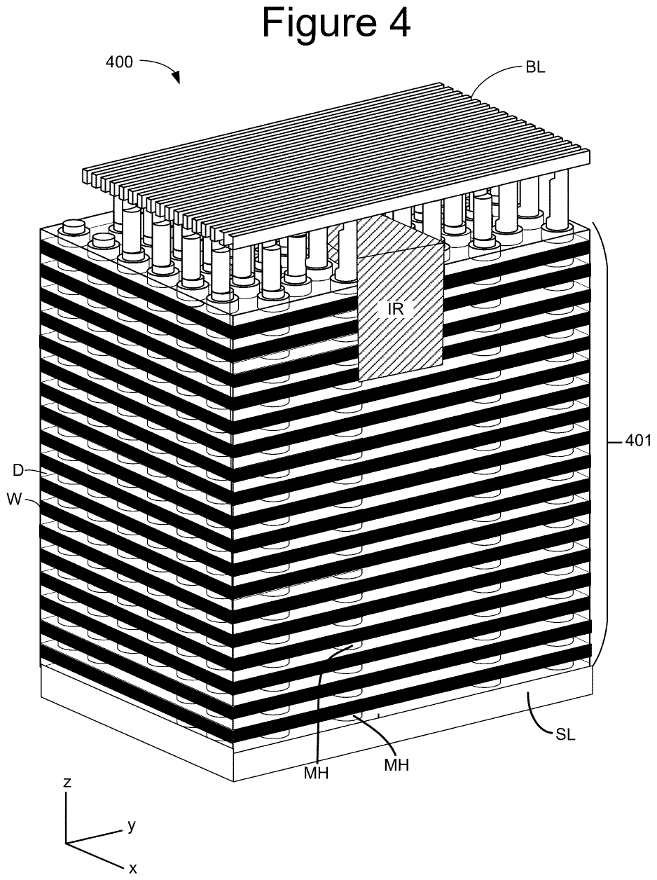

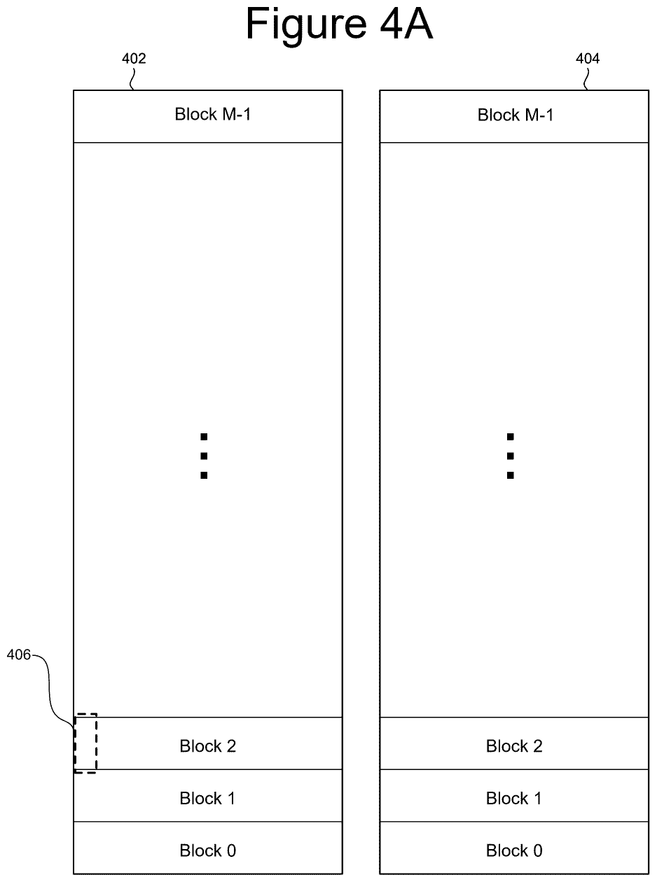

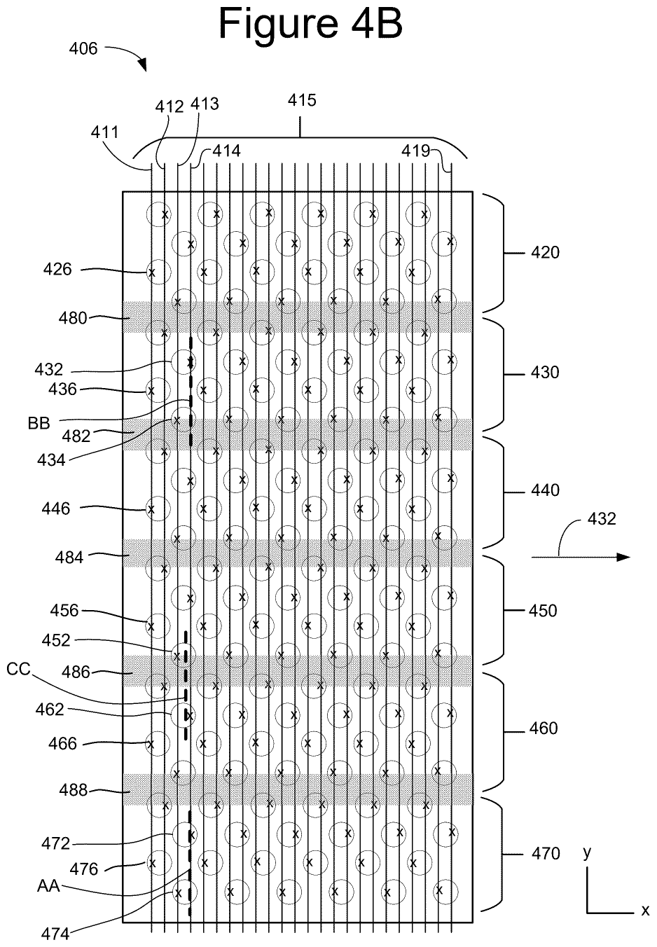

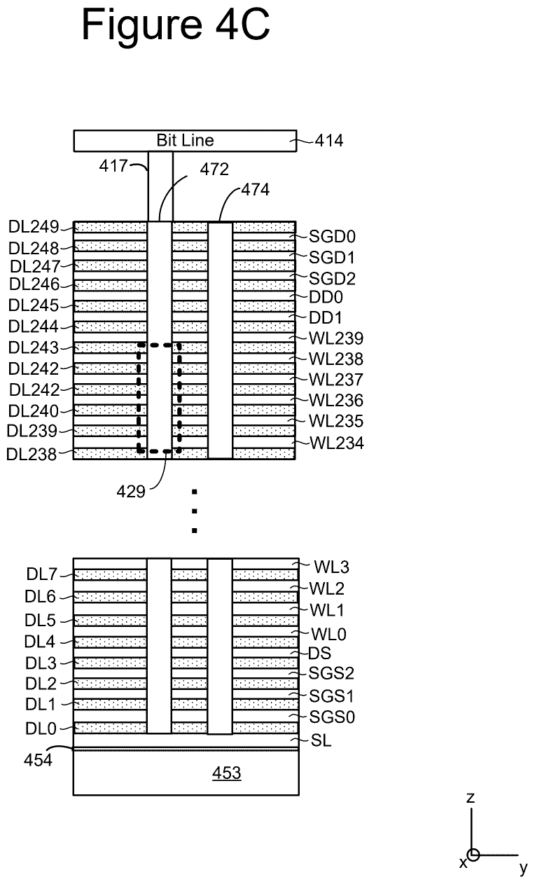

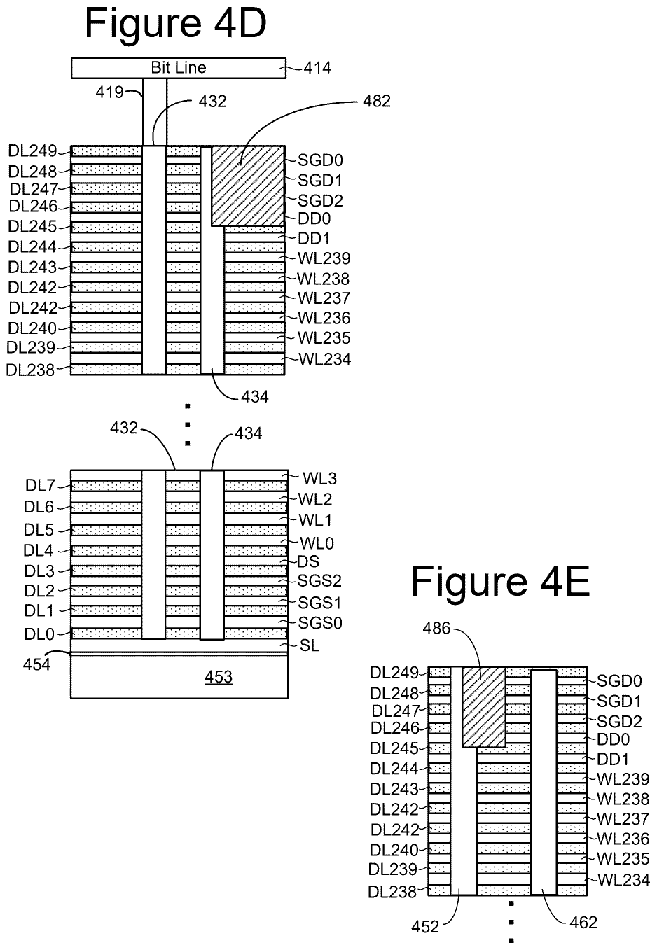

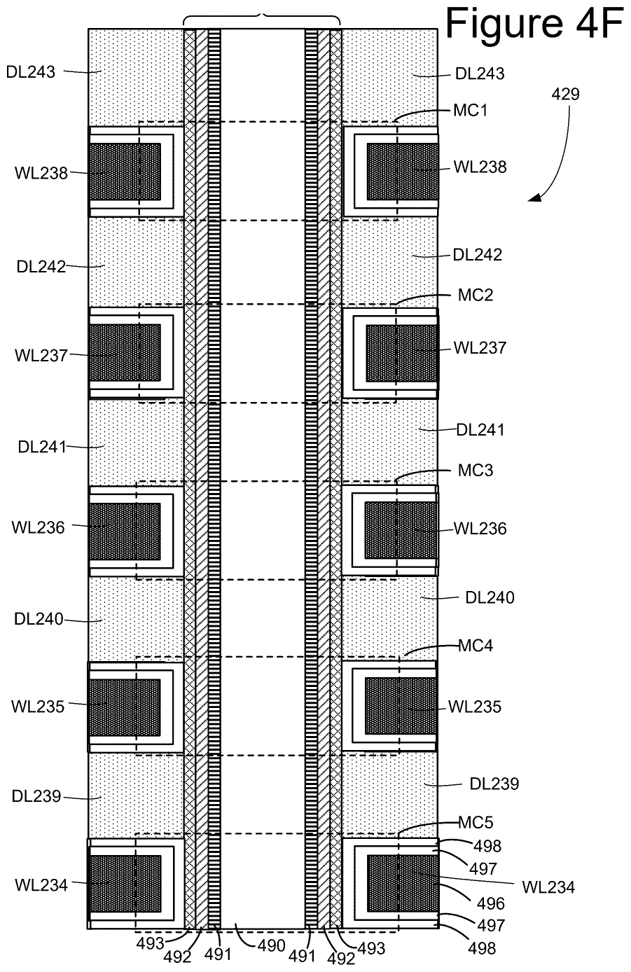

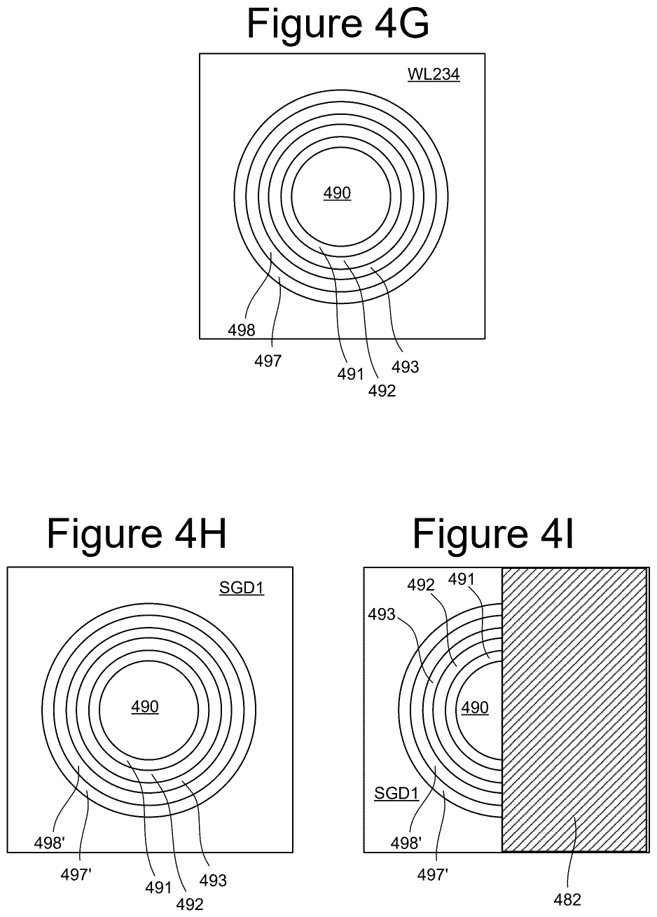

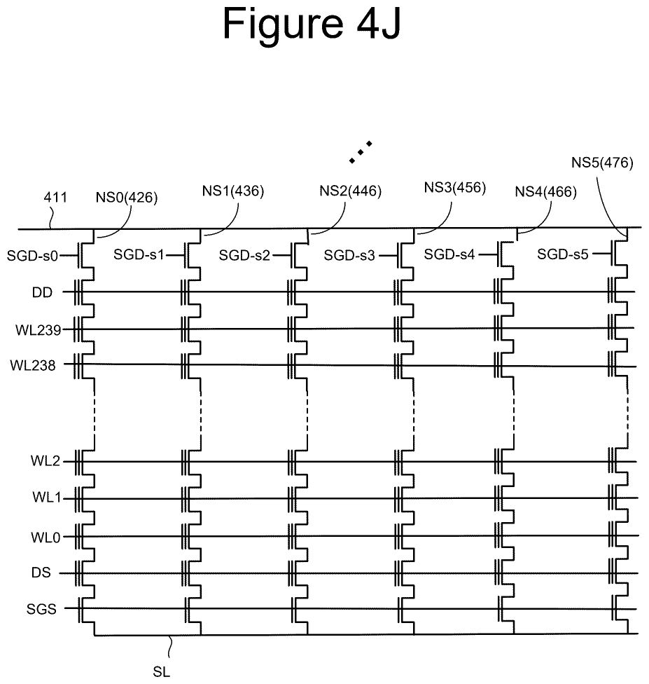

FIG. 4 is a perspective view of a portion of one example embodiment of a monolithic three dimensional memory array/structure that can comprise memory array 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. As will be explained below, in one embodiment the alternating dielectric layers and conductive layers are divided into six (or a different number of) regions (e.g., sub-blocks) by isolation regions IR. FIG. 4 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory array 202 is provided below.

FIG. 4A is a block diagram explaining one example organization of memory array 202, which is divided into two planes 402 and 404. Each plane is then divided into M blocks. In one example, each plane has about 2000 blocks. However, different numbers of blocks and planes can also be used. In on embodiment, a block of memory cells is a unit of erase (e.g., also called an erase block). That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 402/404, more or less than two planes can be implemented. In some embodiments, memory array 202 includes eight planes. In other embodiments, a memory array can include more than eight planes.

FIGS. 4B-4J depict an example three dimensional (“3D”) NAND structure that corresponds to the structure of FIG. 4 and can be used to implement memory array 202 of FIGS. 2A and 2B. FIG. 4B is a block diagram depicting a top view of a portion 406 of Block 2 of plane 402. As can be seen from FIG. 4B, the block depicted in FIG. 4B extends in the direction of 432. In one embodiment, the memory array has many layers; however, FIG. 4B only shows the top layer.

FIG. 4B depicts a plurality of circles that represent the vertical columns, which correspond to the memory holes. Each of the vertical columns include multiple select transistors (also referred to as a select gate or selection gate) and multiple memory cells. In one embodiment, each vertical column implements a NAND string. For example, FIG. 4B labels a subset of the vertical columns/NAND strings 426,432, 436, 446. 456, 462, 466, 472, 474 and 476.

FIG. 4B also depicts a set of bit lines 415, including bit lines 411, 412, 413, 414, . . . 419. FIG. 4B shows twenty four bit lines because only a portion of the block is depicted. It is contemplated that more than twenty four bit lines connected to vertical columns of the block. Each of the circles representing vertical columns has an “x” to indicate its connection to one bit line. For example, bit line 411 is connected to vertical columns 426, 436, 446, 456, 466 and 476.

The block depicted in FIG. 4B includes a set of isolation regions 480, 482, 484, 486 and 488, which are formed of SiO₂; however, other dielectric materials can also be used. Isolation regions 480, 482, 484, 486 and 488 serve to divide the top layers of the block into six regions; for example, the top layer depicted in FIG. 4B is divided into regions 420, 430, 440, 450, 460 and 470 all of which are referred to as sub-blocks. In one embodiment, the isolation regions only divide the layers used to implement select gates so that NAND strings in different sub-blocks can be independently selected. In one example implementation, a bit line only connects to one vertical column/NAND string in each of regions (sub-blocks) 420, 430, 440, 450, 460 and 470. In that implementation, each block has twenty four rows of active columns and each bit line connects to six rows in each block. In one embodiment, all of the six vertical columns/NAND strings connected to a common bit line are connected to the same word line (or set of word lines); therefore, the system uses the drain side selection lines to choose one (or another subset) of the six to be subjected to a memory operation (program, verify, read, and/or erase).

Although FIG. 4B shows each region 420, 430, 440, 450, 460 and 470 having four rows of vertical columns, six regions and twenty four rows of vertical columns in a block, those exact numbers are an example implementation. Other embodiments may include more or less regions per block, more or less rows of vertical columns per region and more or less rows of vertical columns per block. FIG. 4B also shows the vertical columns being staggered. In other embodiments, different patterns of staggering can be used. In some embodiments, the vertical columns are not staggered.

FIG. 4C depicts a portion of one embodiment of a three dimensional memory array 202 showing a cross-sectional view along line AA of FIG. 4B. This cross sectional view cuts through vertical columns (NAND strings) 472 and 474 of region 470 (see FIG. 4B). The structure of FIG. 4C includes three drain side select layers SGD0, SGD1 and SGD2; three source side select layers SGS0, SGS1, and SGS2; three dummy word line layers DD0, DD1, and DDS; two hundred and forty word line layers WL0-WL239 for connecting to data memory cells, and two hundred and fifty dielectric layers D10-DL249. Other embodiments can implement more or less than the numbers described above for FIG. 4C. In one embodiment, SGD0, SGD1 and SGD2 are connected together; and SGDS0, SGS1 and SGS2 are connected together.

Vertical columns 472 and 474 are depicted protruding through the drain side select layers, source side select layers, dummy word line layers and word line layers. In one embodiment, each vertical column comprises a vertical NAND string. Below the vertical columns and the layers listed below is substrate 453, an insulating film 454 on the substrate, and source line SL. The NAND string of vertical column 442 has a source end at a bottom of the stack and a drain end at a top of the stack. As in agreement with FIG. 4B, FIG. 4C show vertical column 442 connected to bit line 414 via connector 417.

For ease of reference, drain side select layers; source side select layers, dummy word line layers and data word line layers collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL249. For example, dielectric layers DL240 is above word line layer WL235 and below word line layer WL236. In one embodiment, the dielectric layers are made from SiO₂. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layers WL0-W239 connect to memory cells (also called data memory cells). Dummy word line layers DD0, DD1 and DS connect to dummy memory cells. A dummy memory cell does not store and is not eligible to store host data, while a data memory cell is eligible to store host data. For purposes of this document, host data is data provided from the host or entity outside of the storage system 100, such as data from a user of the host 102. Host data can be contrasted with system data that is generated by memory system 100 (e.g., L2P tables). In some embodiments, data memory cells and dummy memory cells may have a same structure. Drain side select layers SGD0, SGD1, and SGD2 are used to electrically connect and disconnect NAND strings from bit lines. Source side select layers SGS0, SGS1, and SGS2 are used to electrically connect and disconnect NAND strings from the source line SL.

Note that the stack of word lines WL0-WL239 include two edge word lines at the edges of the stack, including top edge word line WL239 and bottom edge word line WL0. Word lines WL1-WL238 are non-edge word lines.

FIG. 4D depicts a portion of one embodiment of a three dimensional memory array 202 showing a cross-sectional view along line BB of FIG. 4B. This cross sectional view cuts through vertical columns (NAND strings) 432 and 434 of region 430 (see FIG. 4B). FIG. 4D shows the same alternating conductive and dielectric layers as FIG. 4C. FIG. 4D also shows isolation region 482. Isolation regions 480, 482, 484, 486 and 488) occupy space that would have been used for a portion of the memory holes/vertical columns/NAND stings. For example, isolation region 482 occupies space that would have been used for a portion of vertical column 434. More specifically, a portion (e.g., half the diameter) of vertical column 434 has been removed in layers SDG0, SGD1, SGD2, and DD0 to accommodate isolation region 482. Thus, while most of the vertical column 434 is cylindrical (with a circular cross section), the portion of vertical column 434 in layers SDG0, SGD1, SGD2, and DD0 has a semi-circular cross section. In one embodiment, after the stack of alternating conductive and dielectric layers is formed, the stack is etched to create space for the isolation region and that space is then filled in with SiO₂.

FIG. 4E depicts a portion of one embodiment of a three dimensional memory array 202 showing a cross-sectional view along line CC of FIG. 4B. This cross sectional view cuts through vertical columns (NAND strings) 452 and 462 (see FIG. 4B). FIG. 4E shows the same alternating conductive and dielectric layers as FIG. 4C. FIG. 4E also shows isolation region 486 cutting into vertical columns (NAND string) 452.

FIG. 4F depicts a cross sectional view of region 429 of FIG. 4C that includes a portion of vertical column 472. In one embodiment, the vertical columns are round; however, in other embodiments other shapes can be used. In one embodiment, vertical column 472 includes an inner core layer 490 that is made of a dielectric, such as SiO₂. Other materials can also be used. Surrounding inner core 490 is polysilicon channel 491. Materials other than polysilicon can also be used. Note that it is the channel 491 that connects to the bit line and the source line. Surrounding channel 491 is a tunneling dielectric 492. In one embodiment, tunneling dielectric 492 has an ONO structure. Surrounding tunneling dielectric 492 is charge trapping layer 493, such as (for example) Silicon Nitride. Other memory materials and structures can also be used. The technology described herein is not limited to any particular material or structure.

FIG. 4D depicts dielectric layers DLL239, DLL240, DLL241, DLL242 and DLL243, as well as word line layers WLL234, WLL235, WLL236, WLL237, and WLL238.

Each of the word line layers includes a word line region 496 surrounded by an aluminum oxide layer 497, which is surrounded by a blocking oxide layer 498. In other embodiments, the blocking oxide layer can be a vertical layer parallel and adjacent to charge trapping layer 493. The physical interaction of the word line layers with the vertical column forms the memory cells. Thus, a memory cell, in one embodiment, comprises channel 491, tunneling dielectric 492, charge trapping layer 493, blocking oxide layer 498, aluminum oxide layer 497 and word line region 496. For example, word line layer WLL238 and a portion of vertical column 472 comprise a memory cell MC1. Word line layer WL237 and a portion of vertical column 472 comprise a memory cell MC2. Word line layer WLL236 and a portion of vertical column 472 comprise a memory cell MC3. Word line layer WLL235 and a portion of vertical column 472 comprise a memory cell MC4. Word line layer WLL234 and a portion of vertical column 472 comprise a memory cell MC5. In other architectures, a memory cell may have a different structure; however, the memory cell would still be the storage unit.

When a memory cell is programmed, electrons are stored in a portion of the charge trapping layer 493 which is associated with (e.g. in) the memory cell. These electrons are drawn into the charge trapping layer 493 from the channel 491, through the tunneling dielectric 492, in response to an appropriate voltage on word line region 496. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4G shows a cross section of vertical column 472 of FIG. 4F, cut through MC5. Thus, FIG. 4G depicts word line layer WL234, inner core 490, channel 491, tunneling dielectric 492, charge trapping layer 493, aluminum oxide layer 497, and blocking oxide layer 498.

FIG. 4H shows a cross section of vertical column 472 of FIG. 4F, cut through SGD1 (a select gate layer implementing a select gate). Thus, FIG. 4H depicts drain side select line layer SGD1, inner core 490, channel 491, tunneling dielectric 492, charge trapping layer 493, aluminum oxide layer 497, and blocking oxide layer 498.

FIG. 4I shows a cross section of vertical column 434 of FIG. 4D, cut through SGD1. Thus, FIG. 4I depicts drain side select line layer SGD1, inner core 490, channel 491, tunneling dielectric 492, charge trapping layer 493, aluminum oxide layer 497, and blocking oxide layer 498. FIG. 4I also shows a portion of isolation region 482. As can be seen in FIG. 4I, the select gate (select gate layer and select line layer) of vertical column 434 is semicircular in shape (or partially circular in shape) due to vertical column (NAND string) 434 intersecting isolation region 482.

FIG. 4J is a schematic diagram of a portion of the memory array 202 depicted in in FIGS. 4-4I. FIG. 4J shows physical data word lines WL0-WL239 running across the entire block. The structure of FIG. 4J corresponds to a portion 306 in Block 2 of FIG. A, including bit line 411. Within the block, in one embodiment, each bit line is connected to six NAND strings. Thus, FIG. 4J shows bit line connected to NAND string NS0 (which corresponds to vertical column 426), NAND string NS1 (which corresponds to vertical column 436), NAND string NS2 (which corresponds to vertical column 446), NAND string NS3 (which corresponds to vertical column 456), NAND string NS4 (which corresponds to vertical column 466), and NAND string NS5 (which corresponds to vertical column 476). As mentioned above, in one embodiment, SGD0, SGD1 and SGD2 are connected together to operate as a single logical select gate for each sub-block separated by isolation regions (480, 482, 484, 486 and 486) to form SGD-s0, SGD-s1, SGD-s2, SGD-s3, SGD-s4, and SGD-s5. SGS0, SG1 and SGS2 are also connected together to operate as a single logical select gate that is represented in FIG. 4E as SGS. Although the select gates SGD-s0, SGD-s1, SGD-s2, SGD-s3, SGD-s4, and SGD-s5 are isolated from each other due to the isolation regions, the data word lines WL0-WL239 of each sub-block are connected together.

The isolation regions (480, 482, 484, 486 and 486) are used to allow for separate control of sub-blocks. A first sub-block corresponds to those vertical NAND strings controlled by SGD-s0. A second sub-block corresponds to those vertical NAND strings controlled by SGD-s1. A third sub-block corresponds to those vertical NAND strings controlled by SGD-s2. A fourth sub-block corresponds to those vertical NAND strings controlled by SGD-s3. A fifth sub-block corresponds to those vertical NAND strings controlled by SGD-s4. A sixth sub-block corresponds to those vertical NAND strings controlled by SGD-s5.

FIG. 4J only shows the NAND strings connected to bit line 411. However, a full schematic of the block would show every bit line and six vertical NAND strings connected to each bit line.

Although the example memories of FIGS. 4-4J are three dimensional memory structures that includes vertical NAND strings with charge-trapping material, other (2D and 3D) memory structures can also be used with the technology described herein.

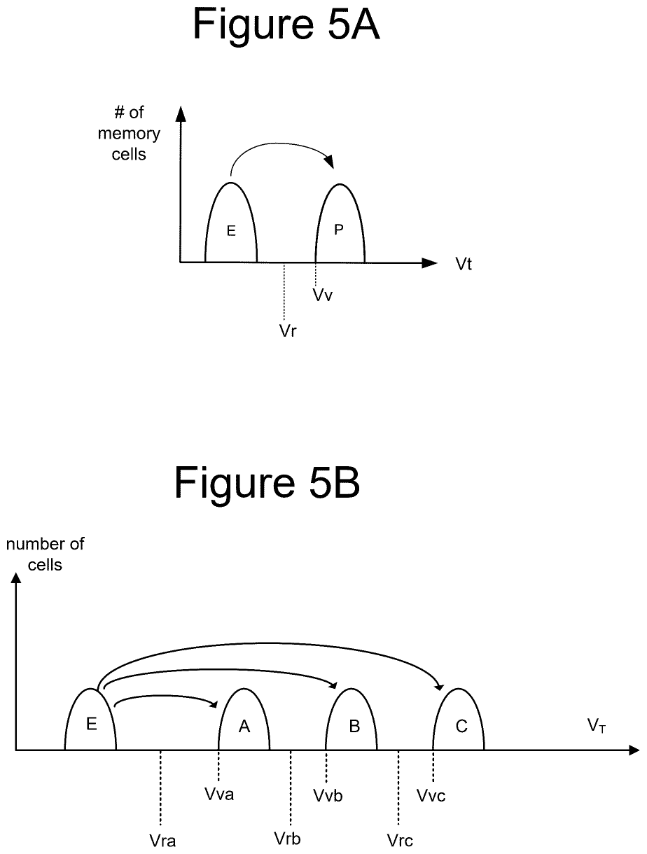

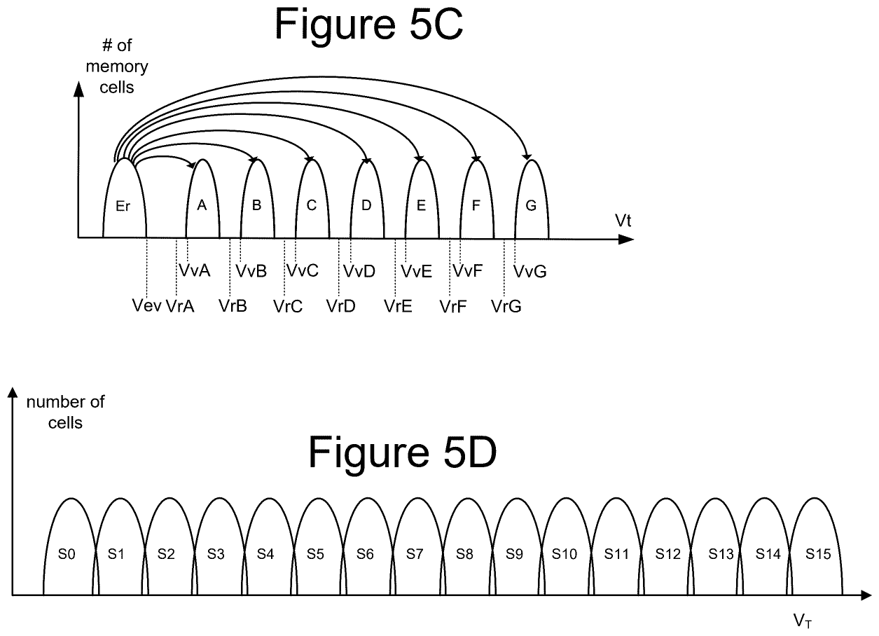

The memory systems discussed above can be erased, programmed (with host data) and read using the control circuit described above. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv.

FIGS. 5B-D illustrate example threshold voltage distributions for the memory array when each memory cell stores multiple bit per memory cell data. Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores two bits of data. Other embodiments may use other data capacities per memory cell (e.g., such as three, four, five or six bits of data per memory cell).

FIG. 5B shows a first threshold voltage distribution E for erased memory cells. Three threshold voltage distributions A, B and C for programmed memory cells are also depicted. In one embodiment, the threshold voltages in the distribution E are negative and the threshold voltages in distributions A, B and C are positive. Each distinct threshold voltage distribution of FIG. 5B corresponds to predetermined values for the set of data bits. In one embodiment, each bit of data of the two bits of data stored in a memory cell are in different logical pages, referred to as a lower page (LP) and an upper page (UP). In other embodiments, all bits of data stored in a memory cell are in a common logical page. The specific relationship between the data programmed into the memory cell and the threshold voltage levels of the cell depends upon the data encoding scheme adopted for the cells. Table 1 provides an example encoding scheme.

TABLE 1

| | E | A | B | C |
|---|---|---|---|---|
| LP | 1 | 0 | 0 | 1 |
| UP | 1 | 1 | 0 | 0 |

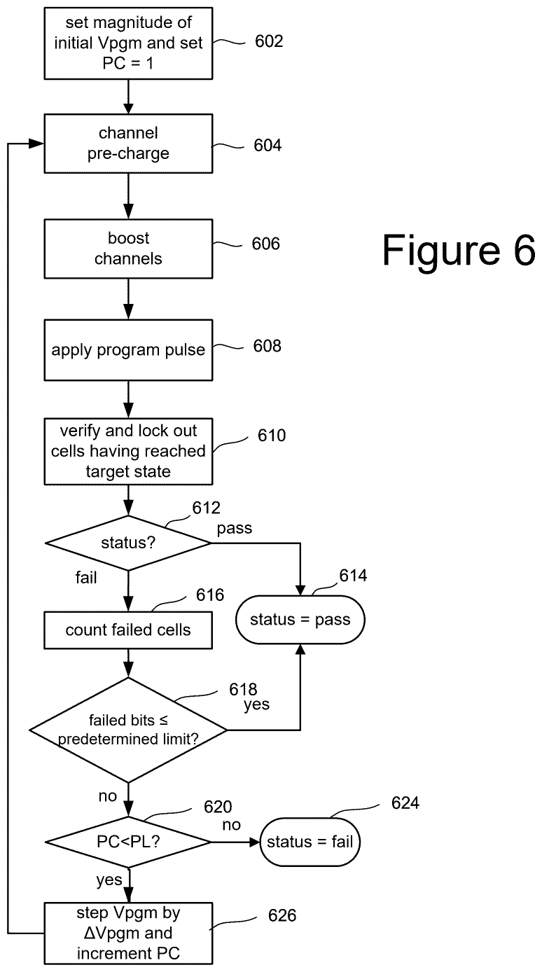

In one embodiment, known as full sequence programming, memory cells can be programmed from the erased data state E directly to any of the programmed data states A, B or C using the process of FIG. 6 (discussed below). For example, a population of memory cells to be programmed may first be erased so that all memory cells in the population are in erased data state E. Then, a programming process is used to program memory cells directly into data states A, B, and/or C. For example, while some memory cells are being programmed from data state E to data state A, other memory cells are being programmed from data state E to data state B and/or from data state E to data state C. The arrows of FIG. 5B represent the full sequence programming. In some embodiments, data states A-C can overlap, with memory controller 120 (or control die 211) relying on error correction to identify the correct data being stored.

FIG. 5C depicts example threshold voltage distributions for memory cells where each memory cell stores three bits of data per memory cells (which is another example of MLC data). FIG. 5C shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. Table 2 provides an example of an encoding scheme for embodiments in which each bit of data of the three bits of data stored in a memory cell are in different logical pages, referred to as a lower page (LP), middle page (MP) and an upper page (UP).

TABLE 2

| | Er | A | B | C | D | E | F | G |
|---|---|---|---|---|---|---|---|---|
| UP | 1 | 1 | 1 | 0 | 0 | 0 | 0 | 1 |
| MP | 1 | 1 | 0 | 0 | 1 | 1 | 0 | 0 |
| LP | 1 | 0 | 0 | 0 | 0 | 1 | 1 | 1 |

FIG. 5C shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in.

FIG. 5C also shows seven verify reference voltages, VvA, VvB, VvC, VvD, VvE, VvF, and VvG. In some embodiments, when programming memory cells to data state A, the system will test whether those memory cells have a threshold voltage greater than or equal to VvA. When programming memory cells to data state B, the system will test whether the memory cells have threshold voltages greater than or equal to VvB. When programming memory cells to data state C, the system will determine whether memory cells have their threshold voltage greater than or equal to VvC. When programming memory cells to data state D, the system will test whether those memory cells have a threshold voltage greater than or equal to VvD. When programming memory cells to data state E, the system will test whether those memory cells have a threshold voltage greater than or equal to VvE. When programming memory cells to data state F, the system will test whether those memory cells have a threshold voltage greater than or equal to VvF. When programming memory cells to data state G, the system will test whether those memory cells have a threshold voltage greater than or equal to VvG. FIG. 5C also shows Vev, which is a voltage level to test whether a memory cell has been properly erased.

In an embodiment that utilizes full sequence programming, memory cells can be programmed from the erased data state Er directly to any of the programmed data states A-G using the process of FIG. 6 (discussed below). For example, a population of memory cells to be programmed may first be erased so that all memory cells in the population are in erased data state Er. Then, a programming process is used to program memory cells directly into data states A, B, C, D, E, F, and/or G. For example, while some memory cells are being programmed from data state ER to data state A, other memory cells are being programmed from data state ER to data state B and/or from data state ER to data state C, and so on. The arrows of FIG. 5C represent the full sequence programming. In some embodiments, data states A-G can overlap, with control die 211 and/or memory controller 120 relying on error correction to identify the correct data being stored. Note that in some embodiments, rather than using full sequence programming, the system can use multi-pass programming processes known in the art.

In general, during verify operations and read operations, the selected word line is connected to a voltage (one example of a reference signal), a level of which is specified for each read operation (e.g., see read compare levels VrA, VrB, VrC, VrD, VrE, VrF, and VrG, of FIG. 5C) or verify operation (e.g. see verify target levels VvA, VvB, VvC, VvD, VvE, VvF, and VvG of FIG. 5C) in order to determine whether a threshold voltage of the concerned memory cell has reached such level. After applying the word line voltage, the conduction current of the memory cell is measured to determine whether the memory cell turned on (conducted current) in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

FIG. 5D depicts threshold voltage distributions when each memory cell stores four bits of data, which is another example of MLC data. FIG. 5D depicts that there may be some overlap between the threshold voltage distributions (data states) S0-S15. The overlap may occur due to factors such as memory cells losing charge (and hence dropping in threshold voltage). Program disturb can unintentionally increase the threshold voltage of a memory cell. Likewise, read disturb can unintentionally increase the threshold voltage of a memory cell. Over time, the locations of the threshold voltage distributions may change. Such changes can increase the bit error rate, thereby increasing decoding time or even making decoding impossible. Changing the read reference voltages can help to mitigate such effects. Using ECC during the read process can fix errors and ambiguities. Note that in some embodiments, the threshold voltage distributions for a population of memory cells storing four bits of data per memory cell do not overlap and are separated from each other. The threshold voltage distributions of FIG. 5D will include read reference voltages and verify reference voltages, as discussed above.

When using four bits per memory cell, the memory can be programmed using the full sequence programming discussed above, or multi-pass programming processes known in the art. Each threshold voltage distribution (data state) of FIG. 5D corresponds to predetermined values for the set of data bits. The specific relationship between the data programmed into the memory cell and the threshold voltage levels of the cell depends upon the data encoding scheme adopted for the cells. Table 3 provides an example of an encoding scheme for embodiments in which each bit of data of the four bits of data stored in a memory cell are in different logical pages, referred to as a lower page (LP), middle page (MP), an upper page (UP) and top page (TP).

TABLE 3

| | S0 | S1 | S2 | S3 | S4 | S5 | S6 | S7 | S8 | S9 | S10 | S11 | S12 | S13 | S14 | S15 |
|---|---|---|---|---|---|---|---|---|---|---|---|---|---|---|---|---|
| TP | 1 | 1 | 1 | 1 | 1 | 0 | 0 | 0 | 0 | 0 | 1 | 1 | 0 | 0 | 0 | 1 |
| UP | 1 | 1 | 0 | 0 | 0 | 0 | 0 | 0 | 1 | 1 | 1 | 1 | 1 | 1 | 0 | 0 |
| MP | 1 | 1 | 1 | 0 | 0 | 0 | 0 | 1 | 1 | 0 | 0 | 0 | 0 | 1 | 1 | 1 |
| LP | 1 | 0 | 0 | 0 | 1 | 1 | 0 | 0 | 0 | 0 | 0 | 1 | 1 | 1 | 1 | 1 |

FIG. 6 is a flowchart describing one embodiment of a process for programming host data (or system data) into memory cells. For purposes of this document, the term program and programming are synonymous with write and writing. In one example embodiment, the process of FIG. 6 is performed for memory array 202 using the one or more control circuits (e.g., system control logic 260, column control circuitry 210, row control circuitry 220) discussed above. In one example embodiment, the process of FIG. 6 is performed by integrated memory assembly 207 using the one or more control circuits (e.g., system control logic 260, column control circuitry 210, row control circuitry 220) of control die 211 to program memory cells on memory die 201. The process includes multiple loops, each of which includes a program phase and a verify phase. The process of FIG. 6 is performed to implement the full sequence programming, as well as other programming schemes including multi-pass programming. When implementing multi-pass programming, the process of FIG. 6 is used to implement any/each pass of the multi-pass programming process.

Typically, the program voltage applied to the control gates (via a selected data word line) during a program operation is applied as a series of program pulses (e.g., voltage pulses). Between programming pulses are a set of verify pulses (e.g., voltage pulses) to perform verification. In many implementations, the magnitude of the program pulses is increased with each successive pulse by a predetermined step size. In step 602 of FIG. 6, the programming voltage signal (Vpgm) is initialized to the starting magnitude (e.g., ~12-16V or another suitable level) and a program counter PC maintained by state machine 3262 is initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 604 the control die will pre-charge channels of NAND strings that include memory cells connected to the selected word line that are to be inhibited from programming. In step 606, NAND strings that include memory cells connected to the selected word line that are to be inhibited from programming have their channels boosted to inhibit programming. Such NAND strings are referred to herein as “unselected NAND strings.” In one embodiment, the unselected word lines receive one or more boosting voltages (e.g., ~7-11 volts), also referred to as pass voltages, to perform boosting schemes. A program inhibit voltage is applied to the bit lines coupled the unselected NAND string.

In step 608, a program voltage pulse of the programming voltage signal Vpgm is applied to the selected word line (the word line selected for programming). If a memory cell on a NAND string should be programmed, then the corresponding bit line is biased at a program enable voltage. In step 608, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 610, program verify is performed and memory cells that have reached their target states are locked out from further programming by the control die. Step 610 includes performing verification of programming by sensing at one or more verify reference levels. In one embodiment, the verification process is performed by testing whether the threshold voltages of the memory cells selected for programming have reached the appropriate verify reference voltage. In step 610, a memory cell may be locked out after the memory cell has been verified (by a test of the Vt) that the memory cell has reached its target state.

If, in step 612, it is determined that all of the memory cells have reached their target threshold voltages (pass), the programming process is complete and successful because all selected memory cells were programmed and verified to their target states. A status of “PASS” is reported in step 614. Otherwise if, in step 612, it is determined that not all of the memory cells have reached their target threshold voltages (fail), then the programming process continues to step 616.

In step 616, the number of memory cells that have not yet reached their respective target threshold voltage distribution are counted. That is, the number of memory cells that have, so far, failed to reach their target state are counted. This counting can be done by state machine 262, memory controller 120, or another circuit. In one embodiment, there is one total count, which reflects the total number of memory cells currently being programmed that have failed the last verify step. In another embodiment, separate counts are kept for each data state.

In step 618, it is determined whether the count from step 616 is less than or equal to a predetermined limit. In one embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 614. In this situation, enough memory cells programmed correctly such that the few remaining memory cells that have not been completely programmed can be corrected using ECC during the read process. In some embodiments, the predetermined limit used in step 618 is below the number of bits that can be corrected by error correction codes (ECC) during a read process to allow for future/additional errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, than the programming process continues at step 620 and the program counter PC is checked against the program limit value (PL). Examples of program limit values include 6, 12, 16, 19, 20 and 30; however, other values can be used. If the program counter PC is not less than the program limit value PL, then the program process is considered to have failed and a status of FAIL is reported in step 624. If the program counter PC is less than the program limit value PL, then the process continues at step 626 during which time the Program Counter PC is incremented by 1 and the programming voltage signal Vpgm is stepped up to the next magnitude. For example, the next pulse will have a magnitude greater than the previous pulse by a step size ΔVpgm (e.g., a step size of 0.1-1.0 volts). After step 626, the process loops back to step 604 and another program pulse is applied to the selected word line (by the control die) so that another iteration (steps 604-626) of the programming process of FIG. 6 is performed.

In one embodiment memory cells are erased prior to programming, and erasing is the process of changing the threshold voltage of one or more memory cells from a programmed data state to an erased data state. For example, changing the threshold voltage of one or more memory cells from state P to state E of FIG. 5A, from states A/B/C to state E of FIG. 5B, from states A-G to state Er of FIG. 5C or from states S1-S15 to state S0 of FIG. 5D.

One technique to erase memory cells in some memory devices is to bias a p-well (or other types of) substrate to a high voltage to charge up a NAND channel. An erase enable voltage (e.g., a low voltage) is applied to control gates of memory cells while the NAND channel is at a high voltage to erase the non-volatile storage elements (memory cells). Herein, this is referred to as p-well erase.

Another approach to erasing memory cells is to generate gate induced drain leakage (GIDL) current to charge up the NAND string channel. An erase enable voltage is applied to control gates of the memory cells, while maintaining the NAND string channel potential to erase the memory cells. Herein, this is referred to as GIDL erase. Both p-well erase and GIDL erase may be used to lower the threshold voltage (Vt) of memory cells.

In one embodiment, the GIDL current is generated by causing a drain-to-gate voltage at a select transistor (e.g., SGD and/or SGS). A transistor drain-to-gate voltage that generates a GIDL current is referred to herein as a GIDL voltage. The GIDL current may result when the select transistor drain voltage is significantly higher than the select transistor control gate voltage. GIDL current is a result of carrier generation, i.e., electron-hole pair generation due to band-to-band tunneling and/or trap-assisted generation. In one embodiment, GIDL current may result in one type of carriers, e.g., holes, predominantly moving into NAND channel, thereby raising potential of the channel. The other type of carriers, e.g., electrons, are extracted from the channel, in the direction of a bit line or in the direction of a source line, by an electric field. During erase, the holes may tunnel from the channel to a charge storage region of memory cells and recombine with electrons there, to lower the threshold voltage of the memory cells.

The GIDL current may be generated at either end of the NAND string. A first GIDL voltage may be created between two terminals of a select transistor (e.g., drain side select transistor) that is connected to or near a bit line to generate a first GIDL current. A second GIDL voltage may be created between two terminals of a select transistor (e.g., source side select transistor) that is connected to or near a source line to generate a second GIDL current. Erasing based on GIDL current at only one end of the NAND string is referred to as a one-sided GIDL erase. Erasing based on GIDL current at both ends of the NAND string is referred to as a two-sided GIDL erase.

In order to more reliably store data in non-volatile memory storage system, a memory health management system based on machine learning is used to predict a defect in the storage system before there is a failure that can affect the data being stored.

A non-volatile memory system stores a pre-trained model in non-volatile memory cells. The model was received pre-trained from a source external to the non-volatile memory system. The non-volatile memory system further includes an inference engine circuit that uses the pre-trained model with one or more metrics gathered during operation of the non-volatile memory system to attempt to predict defects in the non-volatile memory and perform countermeasures to preserve host data prior to a non-recoverable failure in the non-volatile memory due to the defect.

However, to maintain good performance, the pre-trained model needs to be updated and/or optimized. For example, in some cases a block (or other grouping) of memory cells fails (e.g., a memory operation fails) despite that the inference engine circuit predicted that the block of memory cells would not fail. In response to the prediction being wrong, the non-volatile memory system gathers one or more metrics describing the operation of the non-volatile memory system when the block failed (or metrics describing the operation of the non-volatile memory system when multiple blocks failed) and uses those metrics to update and/or optimize the pre-trained model that is stored within the non-volatile memory system.

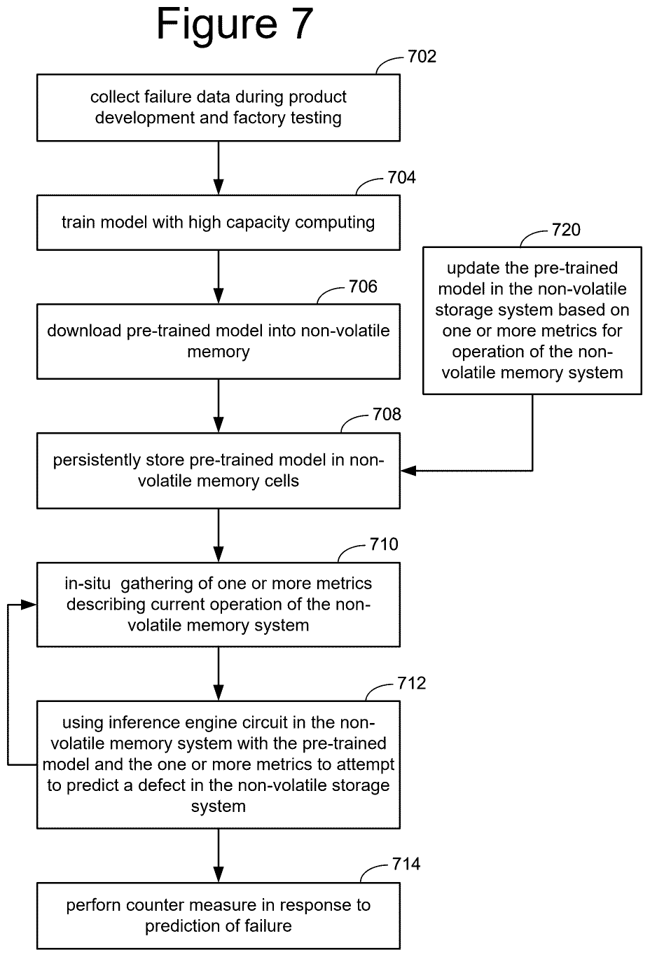

FIG. 7 is a flow chart describing one embodiment of a process for configuring and operating non-volatile memory, including the performing of defect management using Artificial Intelligence with an updating model. In step 702, failure data is collected during product development and testing. Research and Development (“R&D”) engineers spend a lot of resources debugging failing chips during the development of a new memory, diagnose the root causes, and then define the countermeasure. The diagnoses are based on symptoms of a failing chip. For example, sometimes a short between neighboring word lines is detected in the memory array (one example of a defect), and it is observed that threshold voltage distribution of these two word lines and adjacent word lines will have specific symptom including leaky current between word lines. There are multiple types of data generated during the R&D process that can be used to train a model: defective parts per million (“DPPM”) and failure information from memory health test platform, DPPM and failure information from die sort test, NAND device data from Device Assessment Test, DPPM and failure information from final NAND product qualification test, and DPPM and failure information from raw NAND product qualification test.

In step 704, the failure data from step 702 is used (with data from parts that did not fail) to train a model using a high capacity computing platform. In one embodiment, steps 702 and 704 are performed at the factory. In step 706, the pre-trained model (trained in step 704) is downloaded on to the non-volatile memory (e.g., stored in AI blocks 204 or memory array 202). This downloading of the pre-trained model can occur at the factory or in the field. The pre-trained model is then persistently stored in the non-volatile memory (e.g., stored in AI blocks 204 or memory array 202), as per step 708.

Steps 710-714 are performed during user operation of the non-volatile memory (i.e., in the field). In step 710, the control circuit within the non-volatile memory system performs in-situ gathering of one or more metrics describing current operation of the non-volatile memory system. In step 712, the control circuit uses the inference engine circuit 270 in the non-volatile memory system with the pre-trained model (from step 704) and the one or more metrics from step 710 to attempt to predict a defect in the non-volatile memory system. Steps 710 and 712 are repeated during the life of the non-volatile memory system. In one embodiment, steps 710 and 712 are repeated in the background or when the non-volatile memory system is idle. In one embodiment, steps 710 and 712 are performed in response to a pre-failure alarm. When certain conditions occur, a pre-failure alarm is triggered to memory control 120 (750). Examples of pre-failure alarms are unusual number of program loops (e.g., steps 604-626); unusual amount of erase voltages (e.g., pulses) needed to complete erasing; large failed bit count from programming, erasing and/or reading; and unexpected change in program voltage Vpgm, erase voltage, power supply voltage, pass voltages, reference voltages, control voltages, etc. Other conditions can also trigger the pre-failure alarm. In some embodiments, the pre-failure alarm is triggered when an unusual condition exists but before there is a known defect and before there is a non-recoverable failure in the non-volatile storage apparatus due to the defect.

Step 710 includes gathering metrics. Examples of metrics include data word line threshold voltage distribution, non-data word line threshold voltage distribution, failed bit count (“FBC”); word line RC value, bit line RC value, Bitmap, miscellaneous leaky measurements (e.g., leaky analog current or leaky digital DAC between word lines, leaky analog current or leaky digital DAC between bit lines, leaky analog current or leaky digital DAC between WL and channels), bad columns count, bad block count, Iccs (standby current), values of various control signals, program disturb, read disturb, data retention issues, natural Vth (measure Vth width after program operation without verify), program noise, read noise, program speed, erase speed, vboost, verify noise, Neighbor word line disturb, Icell, VSGD margin, Vpass margin, SENSE-Natural-Vt, DIBL, and cross temperature Vt budget. Other metrics can also be gathered.

If a defect is predicted in step 712, then in step 714 the control circuit performs a counter measure in response to that prediction. For example, if the inference engine circuit 270 predicts that a particular block will fail, then the data being stored in that particular block can be copied to another block and the particular block can be retired from further use (or from further use storing host data, which is data received from the host).

In step 720, the control circuit updates the pre-trained model in the non-volatile storage system based on one or more metrics for operation of the non-volatile memory system. The updating can be performed in response to a memory operation failure, or other event. After the model is updated (step 720) the updated model is persistently stored in the non-volatile memory (e.g., stored in AI blocks 204 or memory array 202) in step 708.

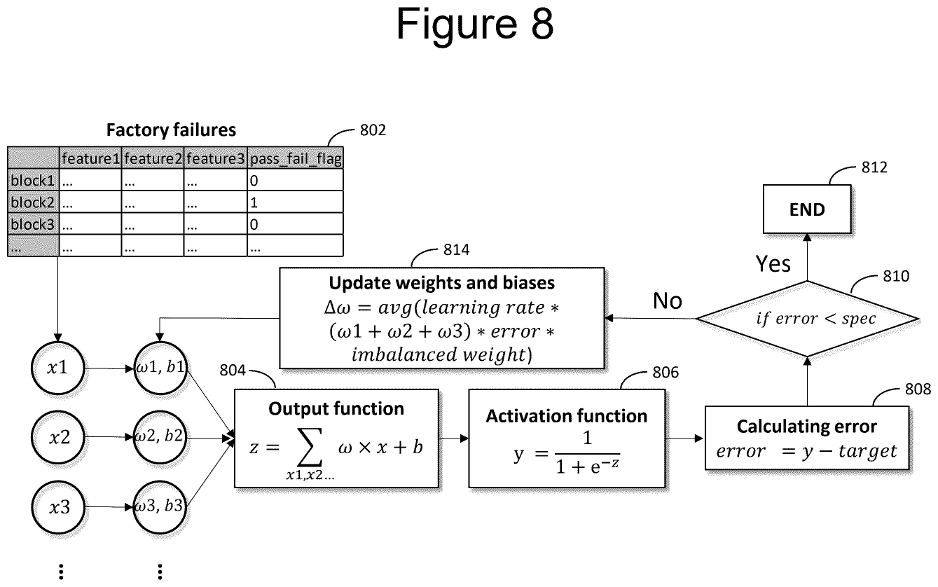

FIG. 8 is a flow chart describing one embodiment of a process for training a model. In one embodiment, FIG. 8 is an example implementation of steps 702 and 704 of FIG. 7 that includes offline training of the model prior to the model being downloaded into the non-volatile memory. In one embodiment, the training of the model (as per FIG. 8) is performed by a high capacity computing system. In one embodiment, the model includes a set of weights and biases (e.g., weights w1,w2, w3, . . . and biases b1, b2, b3, . . . as depicted in FIG. 8). The weights and biases are initialized with random values.

Training the model includes three functions: output function 804, activation function 806 and model modification function 814. Two model parameters, weights and biases are updated during model modification 814. In one embodiment the training process is performed offline with large volume of factory failures.

Failure data collected during product development and factory testing (see step 702) is populated in a database 802. That data (e.g., x1, x2, x3, . . . as depicted in FIG. 8) and the initial set of weights and biases are input into the output function 804. The output function 804 provides the linear fitting for the model (sometimes referred to as a lite model). One example of an output function 804 is:

$$z = {\sum }_{x 1 , x 2 , …} w x + b$$

The result of the output function 804 is provided to activation function 806. Activation function 806 provides the nonlinear fitting for the lite model. One example of the activation function is:

$$y = \frac{1}{1 + {e}^{- z}}$$

The output of the activation function 804 is y, which is the probability of being a bad block (e.g., a block have a defect). In one embodiment, y is a number between zero and one. The error is calculated in step 808:

$$error = y - target$$

In one embodiment, the targets are 0 for good blocks (no defect) and 1 for bad blocks (defect). If, in step 810, the error calculated in step 808 is less than the specified allowed error (spec), then the process of FIG. 8 is completed (step 812) and the model is trained. The specified allowed error (spec) is determined based on experiment and simulation, and can be adjusted based on the targeted performance needs of the memory.

If [in step 810] the error calculated in step 808 is not less than the specified allowed error (spec), then in step 814 the weights and biases of the model are updated based on the error calculated in step 808. For example, weights are updated by Aw:

$$Δ w = average ( learning\_rate * ( w 1 + w 2 + w 3 + … ) * error * imbalance\_weight$$

The learning_rate is used to adjust the speed of change of the weights. If one or more variables or metrics are changing too fast then its effect on the updating of the model can be slowed down. In one embodiment, the learning rate can be thought of as a scaling factor and is a number between zero and one.

The imbalanced_weight is used as an adjustment to give bad blocks (i.e., blocks that failed) a bigger effect on changing the weights than good blocks (blocks that did not fail). In one embodiment, the imbalanced_weight can be two different coefficients: a first coefficient for good blocks and a second coefficient for bad blocks. In one example, the coefficient for a bad block is set to (# of good blocks/# of bad blocks) and the coefficient for a good block is set to 1. This helps accelerate the adjustment of the weights and coefficients from the one or more metrics for bad blocks, since the number of bad blocks is usually much smaller than the number of good blocks.

Note that in one embodiment, coefficients are updated in a similar manner as weights. In another embodiment, coefficients are updated in a different manner (e.g., another technique known in the art). In another embodiment, coefficients are not updated.

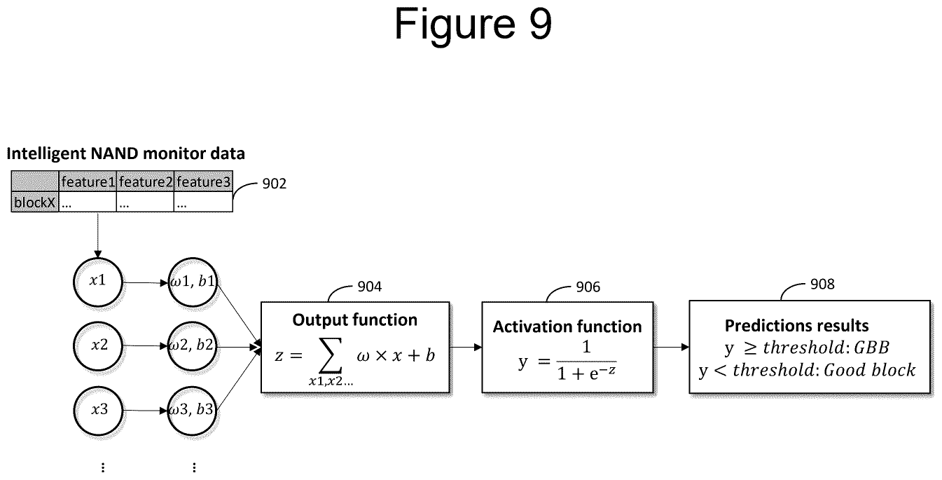

FIG. 9 is a flow chart describing one embodiment of a process for inferencing in order to predict defects in non-volatile memory. In one embodiment, FIG. 9 is an example implementation of step 712 of FIG. 7. The process of FIG. 9 can be performed entirely by a control circuit on memory die 200 (see FIG. 2A) or entirely by a control circuit on integrated memory assembly 207 (see FIG. 2B), rather than by memory controller 120. In one example, the process of FIG. 9 is performed by or at the direction of state machine 262, using other components of System Control Logic 260, Column Control Circuitry 210 and Row Control Circuitry 220. In another embodiment, the process of FIG. 9 is performed by memory controller 120 in combination with System Control Logic 260, Column Control Circuitry 210 and Row Control Circuitry 220.

The one or more metrics gathered in step 710 are stored in database 902. That data (e.g., x1, x2, x3, . . . as depicted in FIG. 9) and the model (e.g. comprising the weights [w1, w2, w3, . . . ] and biases [b1, b2, b3, . . . ]) is input into the output function 904. In one embodiment, output function 904 is mathematically the same as output function 804. The result of the output function 904 is provided to activation function 906. In one embodiment, activation function 906 is mathematically the same as activation function 806. The output of activation function 906 is used by prediction function 908 to predict the results. If the output y of activation function 906 is greater than or equal to a threshold, then the block is a bad block (GBB). If the output y of activation function 906 is less than the threshold, then the block is a good block. The threshold is predefined, based on experimentation and/or simulation, and is adjusted based on the target performance and/or use of the memory.

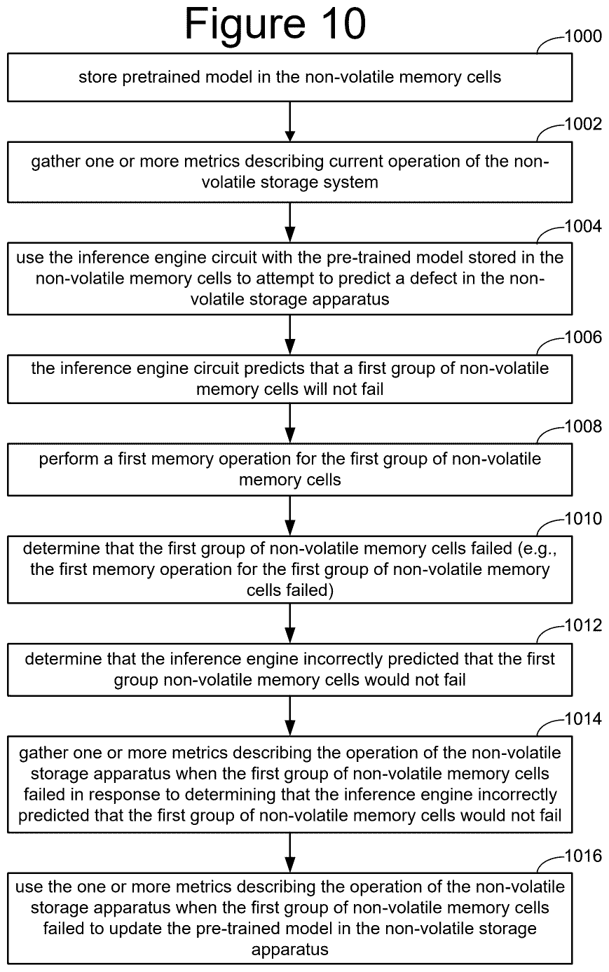

FIG. 10 is a flow chart describing one embodiment of a process for inferencing and updating a pre-trained model. In one embodiment, FIG. 10 is an example implementation of steps 708, 710, 712 and 720 of FIG. 7. Step 1000 of FIG. 10 correlates to step 708. Step 1002 of FIG. 10 correlates to step 710. Steps 1004-1006 of FIG. 10 are an example implementation of step 712. Steps 1008-1016 of FIG. 10 are an example implementation of step 720.

In some example implementations, the process of FIG. 10 can be performed by any one of the one or more control circuits discussed above. The process of FIG. 10 can be performed entirely by a control circuit on memory die 200 (see FIG. 2A) or entirely by a control circuit on integrated memory assembly 207 (see FIG. 2B), rather than by memory controller 120. In one example, the process of FIG. 10 is performed by or at the direction of state machine 262, using other components of System Control Logic 260, Column Control Circuitry 210 and Row Control Circuitry 220. In another embodiment, the process of FIG. 10 is performed by memory controller 120 in combination with System Control Logic 260, Column Control Circuitry 210 and Row Control Circuitry 220.

In step 1000, the control circuit stores the pretrained model in the non-volatile memory cells (e.g., in AI blocks 204). In step 1002, the control circuit gathers one or more metrics describing current operation of the non-volatile storage system. In step 1004, the control circuit uses the inference engine circuit 270 with the pre-trained model stored in the non-volatile memory cells to attempt to predict a defect in the non-volatile storage apparatus, In step 1006, the inference engine circuit 270 predicts that a first group of non-volatile memory cells (e.g., a first block or non-volatile memory cells) will not fail. In step 1008, the control circuit performs a first memory operation for the first group of non-volatile memory cells. In step 1010, the control circuit determines that the first group of non-volatile memory cells failed (e.g., the first memory operation for the first group of non-volatile memory cells failed). In step 1012, the control circuit determines that the inference engine circuit 270 incorrectly predicted that the first group non-volatile memory cells would not fail. In step 1014, the control circuit gathers one or more metrics describing the operation of the non-volatile storage apparatus when the first group of non-volatile memory cells failed in response to determining that the inference engine incorrectly predicted that the first group of non-volatile memory cells would not fail. In step 1016, the control circuit uses the one or more metrics describing the operation of the non-volatile storage apparatus when the first group of non-volatile memory cells failed to update the pre-trained model in the non-volatile storage apparatus.

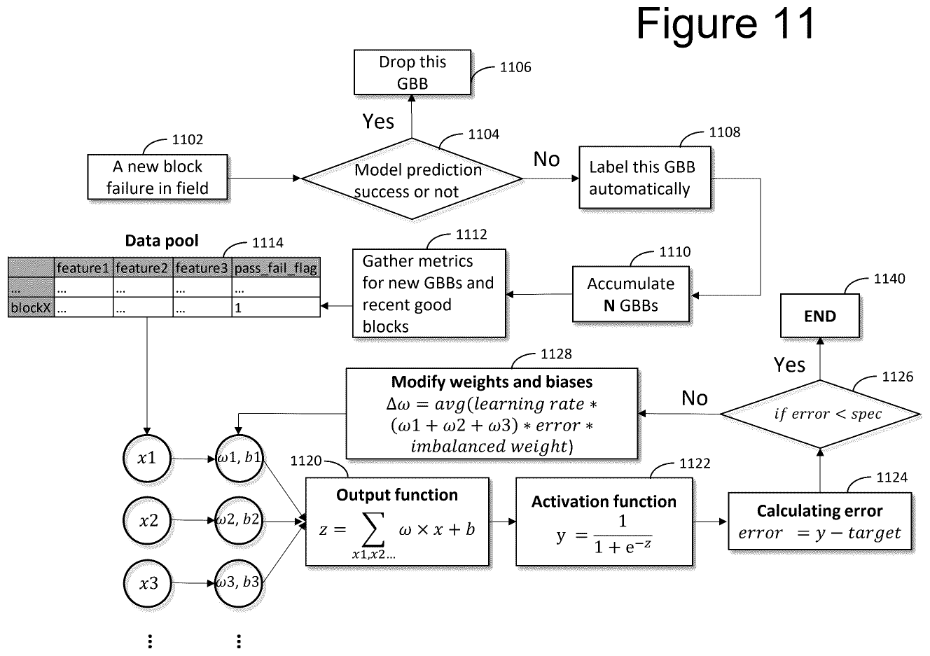

FIG. 11 is a flow chart describing one embodiment of an on-chip process for updating and/or optimizing a pre-trained model. In one embodiment, FIG. 11 is an example implementation of steps 1010-1016 of FIG. 10. In some example implementations, the process of FIG. 11 can be performed by any one of the one or more control circuits discussed above. The process of FIG. 11 can be performed entirely by a control circuit on memory die 200 (see FIG. 2A) or entirely by a control circuit on integrated memory assembly 207 (see FIG. 2B), rather than by memory controller 120. In one example, the process of FIG. 11 is performed by or at the direction of state machine 262, using other components of System Control Logic 260, Column Control Circuitry 210 and Row Control Circuitry 220. In another embodiment, the process of FIG. 11 is performed by memory controller 120 in combination with System Control Logic 260, Column Control Circuitry 210 and Row Control Circuitry 220.

The updating and/or optimizing the pre-trained model of FIG. 11 is somewhat similar to the initial training of the model depicted in FIG. 8. One difference is that new failures in field operation are collected and incorporated into the model as a new data set. If new block failures in field happen but the model makes wrong prediction, this fails will be automatically labeled as bad block data for the model update. After accumulating enough bad blocks (e.g., N GBBs as depicted in FIG. 11), the new bad block data (i.e. one or more metrics describing operation of the memory) will be put into the data pool with recent data for good blocks (i.e. one or more metrics describing operation of the memory) for a future on-chip model update. So, the model can be optimized with updated weights and biases. while in the memory system (e.g., without the high capacity computing used during training). If new failure modes occur during customer operation, which has not been recognized in factory data, this on-chip model optimization can provide more accurate bad block prediction for future bad blocks with new failure modes.

The process of FIG. 11 starts at step 1102 when a block fails in the field (e.g., during end user usage). The control circuit determines in step 1104 whether the inference engine circuit 270 using the model predicted that the block would fail. If the inference engine circuit 270 using the model predicted that the block would fail, and the block failed, then the bad block (GBB) is dropped (retired) from further use for storing host data in step 1106. If the inference engine circuit 270 using the model did not predict that the block would fail, then in step 110-8 the block is labeled as a bad block. For example, the memory controller (or other component) keeps tables that identify whether a block is a good block or a bad block. The control circuit will wait (step 1110) until enough (e.g., N) bad blocks failed after incorrect predictions by the inference engine circuit 270 using the model. That is, the control circuit accumulates N bad blocks (N GBBs). Once N bad blocks have been identified, the control circuit gathers one or more metrics describing the operation of the non-volatile storage apparatus when bad blocks of non-volatile memory cells failed in step 1112 and stores those gathered metrics in data pool 1114. In some embodiment, the control circuit also gathers one or more metrics describing the operation of the non-volatile storage apparatus when good blocks of non-volatile memory cells operated without failing and stores those gathered metrics in data pool 1114.

That data (e.g., x1, x2, x3, . . . as depicted in FIG. 11) in data pool 1114 and the current set of weights (w1, w2, w3, . . . ) and biases (b1, b2, b3, . . . ) are input into the output function 1120. In one embodiment, output function 1120 is mathematically the same as output function 804. The result z of the output function 804 is provided to activation function 1122. In one embodiment, activation function 1122 is mathematically the same as activation function 806. The output y of activation function 1122 is the probability of being a bad block (e.g., a block having a defect). In one embodiment, y is a number between zero and one. The output y of activation function 1122 is used to calculate the error in step 1124, where

$$error = y - target$$

In one embodiment, the targets are 0 for good blocks (no defect) and 1 for bad blocks (defect). If [in step 1126] the error calculated in step 1124 is less than the specified allowed error (spec), then the process of FIG. 11 is completed (step 1140). The specified allowed error (spec) is determined based on experiment and simulation, and can be adjusted based on the targeted performance needs of the memory.

If [in step 1126] the error calculated in step 1124 is not less than the specified allowed error (spec), then in step 1128 the weights and biases of the model are updated based on the error calculated in step 1124. For example, weights are updated by Aw:

$$Δ w = average ( learning\_rate * ( w 1 + w 2 + w 3 + … ) * error * imbalance\_weight$$

Note that in one embodiment, coefficients are updated in a similar manner as weights. In another embodiment, coefficients are updated in a different manner (e.g., another technique known in the art). In another embodiment, coefficients are not updated.

The discussion above describes that the control circuit is configured to: use the inference engine circuit to provide failure predictions for multiple groups of memory cells of the first set of non-volatile memory cells (e.g., step 712 and the process of FIG. 9), determine that some of the multiple groups of memory cells failed and some of the multiple groups of memory cells did not fail (e.g., step 712 and the process of FIG. 9), gather one or more metrics describing the operation of the non-volatile storage apparatus for groups that failed and groups that did not fail (e.g., step 1112), and use the one or more metrics describing the operation of the non-volatile storage apparatus for groups that failed and one or more metrics describing the operation of the non-volatile storage apparatus for groups that did not fail to update the pre-trained model in the non-volatile storage apparatus (e.g., steps 1120-1128).

A non-volatile memory system has been proposed that includes machine learning to predict a defect in the memory system before there is a failure that can affect the data being stored. The machine learning uses an inference engine with a pre-trained model that can be updated on the fly in the filed during end user operation of the memory.

One embodiment includes a non-volatile storage apparatus, comprising: a non-volatile memory structure comprising a first set of non-volatile memory cells configured to store host data and a second set of non-volatile memory cells storing a pre-trained model received pre-trained from a source external to the non-volatile storage apparatus; and a control circuit connected to the non-volatile memory structure and configured to write to and read from the non-volatile memory structure, the control circuit comprises an inference engine circuit within the non-volatile storage apparatus, the inference engine circuit is configured to use the pre-trained model from the second set of non-volatile memory cells to attempt to predict a defect in the non-volatile storage apparatus, the control circuit is configured to: determine that a first group of the first set of non-volatile memory cells failed, determine that the inference engine circuit incorrectly predicted that the first group would not fail, gather one or more metrics describing the operation of the non-volatile storage apparatus when the first group failed, and use the one or more metrics describing the operation of the non-volatile storage apparatus when the first group of non-volatile memory cells failed to update the pre-trained model in the non-volatile storage apparatus.

In one example implementation, the control circuit is configured to perform a first memory operation for the first group of the first set of non-volatile memory cells; and the control circuit is configured to determine that the first group of the first set of non-volatile memory cells failed based on the first memory operation failing.

In one example implementation, the control circuit is configured to use the inference engine circuit to provide a prediction that first group of the first set of non-volatile memory cells will not fail; and the control circuit is configured to determine that the inference engine incorrectly predicted that the first group would not fail in response to the prediction that first group of the first set of non-volatile memory cells will not fail and the first memory operation failing.

In one example implementation, the control circuit is configured to update the pre-trained model using an imbalanced weight to give groups that failed a bigger effect on updating the pre-trained model than groups that did not fail.

In one example implementation, the control circuit is configured to use the inference engine circuit to provide failure predictions for multiple groups of memory cells of the first set of non-volatile memory cells; the control circuit is configured to determine that some of the multiple groups of memory cells failed and some of the multiple groups of memory cells did not fail; the control circuit is configured to gather one or more metrics describing the operation of the non-volatile storage apparatus for groups that failed and groups that did not fail; and the control circuit is configured to use the one or more metrics describing the operation of the non-volatile storage apparatus for groups that failed and one or more metrics describing the operation of the non-volatile storage apparatus for groups that did not fail to update the pre-trained model in the non-volatile storage apparatus.

In one example implementation, the pre-trained model includes weights and biases; and the control circuit is configured to use the one or more metrics describing the operation of the non-volatile storage apparatus for groups that failed and one or more metrics describing the operation of the non-volatile storage apparatus for groups that did not fail to update the pre-trained model in the non-volatile storage apparatus by updating the weights and biases for the pre-trained model based on the one or more metrics describing the operation of the non-volatile storage apparatus for groups that failed and one or more metrics describing the operation of the non-volatile storage apparatus for groups that did not fail.

In one example implementation, the control circuit is configured to update the weights for the pre-trained model based on the update data pool for the weights that are adjusted by an imbalanced weight to give groups that failed a bigger effect on changing the weights than groups that did not fail.

In one example implementation, the non-volatile memory structure and the control circuit are positioned within a memory die assembly; the inference engine is within the memory die assembly; and the pre-trained model is stored in the second set of non-volatile memory cells within the memory die assembly.

In one example implementation, the first set of non-volatile memory cells are arranged as blocks of memory cells; and the first group of the first set of non-volatile memory cells is a first block.

In one example implementation, the control circuit is configured to: determine that a first set of multiple blocks have failed, the first set of multiple blocks includes the first block; gather a first set of one or more metrics describing the operation of the non-volatile memory structure related to the first set of multiple blocks failing; determine that a second set of multiple blocks have successfully performed memory operations; gather a second set of one or more metrics describing the operation of the non-volatile memory structure related to the second set of multiple blocks successfully performing memory operations; and use the gathered first of one or more metrics and the second set of one or more metrics to update the pre-trained model in the non-volatile storage apparatus.

In one example implementation, the control circuit is configured to perform first memory operations for the first set of multiple blocks; the control circuit is configured to perform second memory operations for the second set of multiple blocks; the control circuit is configured to determine that the first set of multiple blocks have failed based on the first memory operations failing; the control circuit is configured to determine that the second set of multiple blocks have failed based on the second memory operations failing; the control circuit is configured to use the inference engine circuit to provide predictions that first set of multiple blocks will not fail; the control circuit is configured to use the inference engine circuit to provide predictions that second set of multiple blocks will not fail; the control circuit is configured to determine that the inference engine incorrectly predicted that the first set of multiple blocks will not fail based on the first memory operations failing; and the control circuit is configured to use the gathered first set of one or more metrics and the second set of one or more metrics to update the pre-trained model in response to determining that the inference engine incorrectly predicted that the first set of multiple blocks will not fail.

In one example implementation, wherein the control circuit is configured to retire the first set of multiple blocks from storing host data.

In one example implementation, wherein the control circuit is configured to perform a counter measure for the first group in response to determining that first group of the first set of non-volatile memory cells failed.

In one example implementation, the first set of non-volatile memory cells are arranged as vertical NAND strings grouped into blocks, each of the blocks includes word lines and channels; and the first group of the first set of non-volatile memory cells is a first block.

One embodiment includes a non-volatile storage apparatus, comprising: a memory die assembly comprising: a non-volatile memory structure including a first set of non-volatile memory cells configured to store host data and a second set of non-volatile memory cells storing a pre-trained model received pre-trained from a source external to the non-volatile storage apparatus, the first set of non-volatile memory cells are arranged as vertical NAND strings grouped into blocks, each of the blocks includes word lines and channels; and a control circuit connected to the non-volatile memory structure and configured to write to and read from the non-volatile memory structure, the control circuit comprises an inference engine circuit positioned in the memory die assembly, the control circuit is configured to: use the inference engine circuit with the pre-trained model from the second set of non-volatile memory cells with one or more metrics describing current operation of the non-volatile storage apparatus in order to attempt to predict defects in the first set of non-volatile memory cells, determine that a first set of the blocks have failed, gather a first set of one or more metrics describing the operation of the non-volatile memory structure related to the first set of multiple blocks failing, determine that a second set of multiple blocks have successfully performed memory operations, gather a second set of one or more metrics describing the operation of the non-volatile memory structure related to the second set of multiple blocks successfully performing memory operations, and use the gathered first of one or more metrics and the second set of one or more metrics to update the pre-trained model in the non-volatile storage apparatus.

In one example implementation, the control circuit is configured to use the inference engine circuit to attempt to predict defects in the first set of non-volatile memory cells including using the inference engine circuit to provide a prediction that first set of blocks will not fail and the second set of blocks will not fail; the control circuit is configured to determine that the inference engine incorrectly predicted that the first set of blocks would not fail in response to determining that the first set of the blocks have failed; and the control circuit is configured to update the pre-trained model in response to determining that the inference engine incorrectly predicted that the first set of blocks would not fail.

In one example implementation, the control circuit is configured to update the pre-trained model using an imbalanced weight to give the first set of multiple blocks that failed a bigger effect on updating the model than the second set of multiple blocks that successfully performed memory operations.

One embodiment includes a method, comprising: storing a pre-trained model in non-volatile memory cells of a non-volatile storage system; the non-volatile storage system gathering one or more metrics describing current operation of the non-volatile storage system; using an inference engine in the non-volatile storage system with the pre-trained model and the one or more metrics to attempt to predict a defect in the non-volatile storage system including providing a prediction about a first block of non-volatile memory cells that did not include predicting the first block failing for its intended use; the non-volatile storage system determining that the first block failed; the non-volatile storage system determining that the inference engine's prediction about the first block was incorrect; the non-volatile storage system gathering one or more metrics describing the operation of the first block that failed; and the non-volatile storage system using the one or more metrics describing the operation of the first block that failed to update the model on the non-volatile storage system.

In one example implementation further comprises performing a first memory operation for the first block, the determining that the first block failed comprises determining that the first the first memory operation failed.

In one example implementation, the using the one or more metrics describing the operation of the first block that failed to update the model on the non-volatile storage system comprises using an imbalanced weight to adjust changes to weights of the model in order to give blocks that failed a bigger effect on updating the model than blocks that did not fail.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A non-volatile storage apparatus, comprising:
a non-volatile memory structure comprising a first set of non-volatile memory cells configured to store host data and a second set of non-volatile memory cells storing a pre-trained model received pre-trained from a source external to the non-volatile storage apparatus; and
a control circuit connected to the non-volatile memory structure and configured to write to and read from the non-volatile memory structure, the control circuit comprises an inference engine circuit within the non-volatile storage apparatus, the inference engine circuit is configured to use the pre-trained model from the second set of non-volatile memory cells to attempt to predict a defect in the non-volatile storage apparatus, the control circuit is configured to:
determine that a first group of the first set of non-volatile memory cells failed,
determine that the inference engine circuit incorrectly predicted that the first group would not fail,
gather one or more metrics describing the operation of the non-volatile storage apparatus when the first group failed, and
use the one or more metrics describing the operation of the non-volatile storage apparatus when the first group of non-volatile memory cells failed to update the pre-trained model in the non-volatile storage apparatus.

2. The non-volatile storage apparatus of claim 1, wherein:
the control circuit is configured to perform a first memory operation for the first group of the first set of non-volatile memory cells; and
the control circuit is configured to determine that the first group of the first set of non-volatile memory cells failed based on the first memory operation failing.

3. The non-volatile storage apparatus of claim 2, wherein:
the control circuit is configured to use the inference engine circuit to provide a prediction that first group of the first set of non-volatile memory cells will not fail; and
the control circuit is configured to determine that the inference engine incorrectly predicted that the first group would not fail in response to the prediction that first group of the first set of non-volatile memory cells will not fail and the first memory operation failing.

4. The non-volatile storage apparatus of claim 1, wherein:
the control circuit is configured to update the pre-trained model using an imbalanced weight to give groups that failed a bigger effect on updating the pre-trained model than groups that did not fail.

5. The non-volatile storage apparatus of claim 1, wherein:
the control circuit is configured to use the inference engine circuit to provide failure predictions for multiple groups of memory cells of the first set of non-volatile memory cells;
the control circuit is configured to determine that some of the multiple groups of memory cells failed and some of the multiple groups of memory cells did not fail;
the control circuit is configured to gather one or more metrics describing the operation of the non-volatile storage apparatus for groups that failed and groups that did not fail; and
the control circuit is configured to use the one or more metrics describing the operation of the non-volatile storage apparatus for groups that failed and one or more metrics describing the operation of the non-volatile storage apparatus for groups that did not fail to update the pre-trained model in the non-volatile storage apparatus.

6. The non-volatile storage apparatus of claim 5, wherein:
the pre-trained model includes weights and biases; and
the control circuit is configured to use the one or more metrics describing the operation of the non-volatile storage apparatus for groups that failed and one or more metrics describing the operation of the non-volatile storage apparatus for groups that did not fail to update the pre-trained model in the non-volatile storage apparatus by updating the weights and biases for the pre-trained model based on the one or more metrics describing the operation of the non-volatile storage apparatus for groups that failed and one or more metrics describing the operation of the non-volatile storage apparatus for groups that did not fail.

7. The non-volatile storage apparatus of claim 6, wherein:
the control circuit is configured to update the weights for the pre-trained model based on one or more error factors for the weights that are adjusted by an imbalanced weight to give groups that failed a bigger effect on changing the weights than groups that did not fail.

8. The non-volatile storage apparatus of claim 1, wherein:
the non-volatile memory structure and the control circuit are positioned within a memory die assembly;
the inference engine is within the memory die assembly; and
the pre-trained model is stored in the second set of non-volatile memory cells within the memory die assembly.

9. The non-volatile storage apparatus of claim 1, wherein:
the first set of non-volatile memory cells are arranged as blocks of memory cells; and
the first group of the first set of non-volatile memory cells is a first block.

10. The non-volatile storage apparatus of claim 9, wherein the control circuit is configured to:
determine that a first set of multiple blocks have failed, the first set of multiple blocks includes the first block;
gather a first set of one or more metrics describing the operation of the non-volatile memory structure related to the first set of multiple blocks failing;
determine that a second set of multiple blocks have successfully performed memory operations;
gather a second set of one or more metrics describing the operation of the non-volatile memory structure related to the second set of multiple blocks successfully performing memory operations; and
use the gathered first of one or more metrics and the second set of one or more metrics to update the pre-trained model in the non-volatile storage apparatus.

11. The non-volatile storage apparatus of claim 10, wherein:
the control circuit is configured to perform first memory operations for the first set of multiple blocks;
the control circuit is configured to perform second memory operations for the second set of multiple blocks;
the control circuit is configured to determine that the first set of multiple blocks have failed based on the first memory operations failing;
the control circuit is configured to determine that the second set of multiple blocks have failed based on the second memory operations failing;
the control circuit is configured to use the inference engine circuit to provide predictions that first set of multiple blocks will not fail;
the control circuit is configured to use the inference engine circuit to provide predictions that second set of multiple blocks will not fail;
the control circuit is configured to determine that the inference engine incorrectly predicted that the first set of multiple blocks will not fail based on the first memory operations failing; and
the control circuit is configured to use the gathered first set of one or more metrics and the second set of one or more metrics to update the pre-trained model in response to determining that the inference engine incorrectly predicted that the first set of multiple blocks will not fail.

12. The non-volatile storage apparatus of claim 9, wherein:
wherein the control circuit is configured to retire the first set of multiple blocks from storing host data.

13. The non-volatile storage apparatus of claim 1, wherein:
wherein the control circuit is configured to perform a counter measure for the first group in response to determining that first group of the first set of non-volatile memory cells failed.

14. The non-volatile storage apparatus of claim 1, wherein:
the first set of non-volatile memory cells are arranged as vertical NAND strings grouped into blocks, each of the blocks includes word lines and channels; and
the first group of the first set of non-volatile memory cells is a first block.

15. A non-volatile storage apparatus, comprising:
a memory die assembly comprising:
a non-volatile memory structure including a first set of non-volatile memory cells configured to store host data and a second set of non-volatile memory cells storing a pre-trained model received pre-trained from a source external to the non-volatile storage apparatus, the first set of non-volatile memory cells are arranged as vertical NAND strings grouped into blocks, each of the blocks includes word lines and channels; and
a control circuit connected to the non-volatile memory structure and configured to write to and read from the non-volatile memory structure, the control circuit comprises an inference engine circuit positioned in the memory die assembly, the control circuit is configured to:
use the inference engine circuit with the pre-trained model from the second set of non-volatile memory cells with one or more metrics describing current operation of the non-volatile storage apparatus in order to attempt to predict defects in the first set of non-volatile memory cells,
determine that a first set of the blocks have failed,
gather a first set of one or more metrics describing the operation of the non-volatile memory structure related to the first set of multiple blocks failing, determine that a second set of multiple blocks have successfully performed memory operations,
gather a second set of one or more metrics describing the operation of the non-volatile memory structure related to the second set of multiple blocks successfully performing memory operations, and
use the gathered first of one or more metrics and the second set of one or more metrics to update the pre-trained model in the non-volatile storage apparatus.

16. The non-volatile storage apparatus of claim 15, wherein:
the control circuit is configured to use the inference engine circuit to attempt to predict defects in the first set of non-volatile memory cells including using the inference engine circuit to provide a prediction that first set of blocks will not fail and the second set of blocks will not fail;
the control circuit is configured to determine that the inference engine incorrectly predicted that the first set of blocks would not fail in response to determining that the first set of the blocks have failed; and
the control circuit is configured to update the pre-trained model in response to determining that the inference engine incorrectly predicted that the first set of blocks would not fail.

17. The non-volatile storage apparatus of claim 15, wherein:
the control circuit is configured to update the pre-trained model using an imbalanced weight to give the first set of multiple blocks that failed a bigger effect on updating the model than the second set of multiple blocks that successfully performed memory operations.

18. A method, comprising:
storing a pre-trained model in non-volatile memory cells of a non-volatile storage system;
the non-volatile storage system gathering one or more metrics describing current operation of the non-volatile storage system;
using an inference engine in the non-volatile storage system with the pre-trained model and the one or more metrics to attempt to predict a defect in the non-volatile storage system including providing a prediction about a first block of non-volatile memory cells that did not include predicting the first block failing for its intended use;
the non-volatile storage system determining that the first block failed;
the non-volatile storage system determining that the inference engine's prediction about the first block was incorrect;
the non-volatile storage system gathering one or more metrics describing the operation of the first block that failed; and
the non-volatile storage system using the one or more metrics describing the operation of the first block that failed to update the model on the non-volatile storage system.

19. The method of claim 18, further comprising:
performing a first memory operation for the first block, the determining that the first block failed comprises determining that the first the first memory operation failed.

20. The method of claim 18, wherein:
the using the one or more metrics describing the operation of the first block that failed to update the model on the non-volatile storage system comprises using an imbalanced weight to adjust changes to weights of the model in order to give blocks that failed a bigger effect on updating the model than blocks that did not fail.
